(19) United States
(12) Patent Application Publication
(10) Pub. No.: US 2025/0390631 A1
(43) Pub. Date: Dec. 25, 2025

(54) Continuous Improvement Methodology for Digital Engineering

(71) Applicant: AUBURN UNIVERSITY, Auburn, AL (US)

(72) Inventors: Allison B. LEDFORD, Auburn, AL (US); Gregory HARRIS, Auburn, AL (US); Ashley YARBROUGH, Auburn, AL (US); Erin GARCIA, Auburn, AL (US)

(21) Appl. No.: 18/750,186

(22) Filed: Jun. 21, 2024

(51) Int. Cl. G06F 30/20; G05B 19/042

(52) U.S. Cl. CPC G06F 30/20; G05B 19/0426; G05B 2219/34333

(57) ABSTRACT

A method for improving production of a physical product may include applying a data element mapping analysis to a current state of a system. The method may further include evaluating results of the application of the data element mapping analysis to identify and prioritize data threads of the system for increased efficiency. Additionally, the method may include adjusting, as a function of the prioritization of the data threads, a subset of the data threads of the system to improve one or more metrics of the system associated with waste that impedes efficiency. Further, the method may include utilizing the adjusted data threads to increase an efficiency associated with production of a physical product produced by the system.

### BACKGROUND

The present disclosure relates to manufacturing physical products and more particularly to improving physical products using data element mapping and analysis.

Typically, a physical product undergoes a process that involves design, testing, manufacturing, and use over its lifecycle. Within each of those phases, operations may be performed in which data regarding the physical product (e.g., dimensions, materials, configuration, etc.) is produced and/or transferred for use in another operation. However, in conventional systems, inefficiencies exist in the flow of data that would otherwise improve one or more operations that would affect the quality of the product (e.g., testing and/or use data that may affect the lifespan, durability, etc. of the product) or efficiency with which the product can be manufactured (e.g., data from the manufacturing phase that could be utilized in the design phase). For example, data may be lost, directed to operations that are not affected by the data, duplicative of other data, encoded in an inefficient format, or transferred in an inefficient manner (e.g., manually). Further, overhauling the entire flow of data through a system to resolve the inefficiencies may be time and/or cost prohibitive.

### SUMMARY

According to one aspect, a method for improving production of a physical product may include applying a data element mapping analysis to a current state of a system. The method may further include evaluating results of the application of the data element mapping analysis to identify and prioritize data threads of the system for increased efficiency. Additionally, the method may include adjusting, as a function of the prioritization of the data threads, a subset of the data threads of the system to improve one or more metrics of the system associated with waste that impedes efficiency. Further, the method may include utilizing the adjusted data threads to increase an efficiency associated with production of a physical product produced by the system.

In some embodiments, applying the data element mapping analysis may include performing functional level mapping and analysis, data vessel mapping and analysis, and data element level mapping and analysis. Evaluating results of the application of the data element mapping analysis may include creating a directed graph data structure in which nodes represent data element instances and edges between the nodes indicate linked relationships. Creating a directed graph data structure may include creating the directed graph data structure based on a table data structure representative of obtained data indicative of functions, data vessels, and data elements associated with the data threads within the system in the current state.

Creating the directed graph data structure based on a table data structure may, in some embodiments, include creating the directed graph data structure based on a table data structure in which rows represent data element instances and columns represent attributes of each corresponding data element instance. In some embodiments, creating the directed graph data structure may include flagging one or more of the nodes or edges as a function of an evaluation based on a set of predefined waste categories. Flagging one or more of the nodes or edges as a function of an evaluation based on a set of predefined waste categories may include flagging one or more of the nodes or edges based on a determined presence of form related waste, excess data related waste, error related waste, separation related waste, delay related waste, change related waste, manual intervention related waste, or storage related waste. In some embodiments, evaluating results of the application of the data element mapping analysis to identify and prioritize data threads of the system may include determining current state metrics for the current state of the system based on the flagged directed graph structure.

Determining the current state metrics may include determining one or more of a percentage of form related waste, a percentage of excess data related waste, a percentage of change related waste, a percentage of separation related waste, a percentage of manual intervention related waste, a percentage of potential storage related waste, a variation index, an estimated number of labor hours for the system, an estimated number of labor hours for each data element, a level of automation, a centrality index, a media disruption index, a first pass yield index, a count of disparate storage locations for data element instances, a count of transfers for data element instances, a count of manual interventions indicative of manual transfers of unique data elements, a count of forms used with each data element instance, or actor data access needs indicative of a number of times that a data element or data vessel changes actor access. In some embodiments, the method may additionally include prioritizing the data threads of the system as a function of the determined current state metrics. Prioritizing data threads as a function of the determined current state metrics may include prioritizing data threads as a function of a capacity of each data thread to improve upon the current state metrics of the system. In some embodiments, prioritizing data threads as a function of the determined current state metrics includes identifying one or more key data threads as a function of one or more of a determined amount of waste, estimated labor hours, level of automation, or actor access needs.

Adjusting a subset of the data threads as a function of the prioritization of the data threads may include removing one or more data elements determined to be excessive while preserving an order in which the data elements flow to one or more actors. In some embodiments, adjusting a subset of the data threads as a function of the prioritization of the data threads comprises identifying one or more data element instances linked to multiple preceding data element instances with OR logic. The method may also include selecting one of the data element instances linked with OR logic to remain linked to a current data element instance and unlinking other data element instances. Further, the method may include deleting data element instances that have no links. In some embodiments, the method may include determining an improved state of the data threads of the system, verifying the improved state of the data threads of the system, developing an improved system architecture based on the improved state of the data threads, verifying and validating the improved system architecture, implementing the improved system architecture, and verifying implementation of the improved system architecture. Verifying and validating the improved system architecture may include verifying whether the improved data threads achieve requirements established for the system. The method may further include, after utilizing the adjusted data threads to increase an efficiency associated with production, adjusting, as a function of the prioritization of the data threads, a second subset of the data threads to further improve the one or more metrics of the system.

In another aspect, a device may include circuitry configured to apply a data element mapping analysis to a current state of a system. The circuitry may also be configured to evaluate results of the application of the data element mapping analysis to identify and prioritize data threads of the system for increased efficiency. Further, the circuitry may be configured to adjust, as a function of the prioritization of the data threads, a subset of the data threads of the system to improve one or more metrics of the system associated with waste that impedes efficiency, and utilize the adjusted data threads to increase an efficiency associated with production of a physical product produced by the system. The circuitry may be configured to perform any of the operations of the method described above.

In another aspect, one or more machine-readable storage media may include instructions stored thereon that, in response to being executed, cause a compute device to apply a data element mapping analysis to a current state of a system. The instructions may additionally cause the compute device to evaluate results of the application of the data element mapping analysis to identify and prioritize data threads of the system for increased efficiency. Further, the instructions may cause the compute device to adjust, as a function of the prioritization of the data threads, a subset of the data threads of the system to improve one or more metrics of the system associated with waste that impedes efficiency and utilize the adjusted data threads to increase an efficiency associated with production of a physical product produced by the system. The instructions may also cause the compute device to perform any of the operations of the method described above.

### BRIEF DESCRIPTION OF THE DRAWINGS

The concepts described herein are illustrated by way of example and not by way of limitation in the accompanying figures. For simplicity and clarity of illustration, elements illustrated in the figures are not necessarily drawn to scale. Where considered appropriate, reference labels have been repeated among the figures to indicate corresponding or analogous elements. The detailed description particularly refers to the accompanying figures in which:

FIG. 1 is a block diagram of at least one embodiment of a method for providing continuous improvement for digital engineering;

FIG. 2 is a block diagram of at least one embodiment of a system for which the method for continuous improvement for digital engineering may be performed to provide improvement to an output of the system;

FIG. 3 is a simplified block diagram of at least one embodiment of a compute device of the system of FIG. 2;

FIGS. 4-9 are flowcharts of at least one embodiment of a method for providing continuous improvement for digital engineering to improve an output of the system of FIG. 2;

FIG. 10 is a detailed diagram of an operation of the method of FIG. 1;

FIGS. 11 and 12 are flow diagrams of embodiments of systems for improving a physical output using data element mapping an analysis;

FIG. 13 is a diagram of an embodiment of a function data object that may be utilized in data element mapping and analysis;

FIG. 14 is a diagram of embodiments of a data vessel data object and a connection data object that may be utilized in data element mapping and analysis:

FIG. 15 is a diagram of an embodiment of a method that may be performed in connection with data element mapping and analysis;

FIG. 16 is a diagram of an embodiment of a data element instance data object that may be utilized in data element mapping and analysis;

FIG. 17 is a flow diagram that may be utilized in connection with data element mapping and analysis;

FIG. 18 is a detailed diagram of an operation of the method of FIG. 1;

FIG. 19 is a diagram of a directed graph data structure that may be produced according to an operation of the method of FIG. 1;

FIG. 20 is a diagram of a flagged directed graph data structure that may be produced according to an operation of the method of FIG. 1; and

FIGS. 21-26 are detailed diagrams of operations of the method of FIG. 1.

### DETAILED DESCRIPTION OF THE DRAWINGS

While the concepts of the present disclosure are susceptible to various modifications and alternative forms, specific embodiments thereof have been shown by way of example in the drawings and will be described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

References in the specification to “one embodiment,” “an embodiment,” “an illustrative embodiment,” etc., indicate that the embodiment described may include a particular feature, structure, or characteristic, but every embodiment may or may not necessarily include that particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described. Additionally, it should be appreciated that items included in a list in the form of “at least one A, B, and C” can mean (A); (B); (C); (A and B); (A and C); (B and C); or (A, B, and C). Similarly, items listed in the form of “at least one of A, B, or C” can mean (A); (B); (C); (A and B); (A and C); (B and C); or (A, B, and C).

The disclosed embodiments may be implemented, in some cases, in hardware, firmware, software, or any combination thereof. The disclosed embodiments may also be implemented as instructions carried by or stored on a transitory or non-transitory machine-readable (e.g., computer-readable) storage medium, which may be read and executed by one or more processors. A machine-readable storage medium may be embodied as any storage device, mechanism, or other physical structure for storing or transmitting information in a form readable by a machine (e.g., a volatile or non-volatile memory, a media disc, or other media device).

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features.

As used herein, the term “data object” may include a logical container for data. A data object may include an instance of an object in a software application implemented with an object-oriented programming language. A data object may include data formatted in an electronic data interchange (EDI) format, such as an extensible Markup Language (XML) object, a JavaScript Object Notation (JSON) object, or other EDI-formatted object. A data object may include one or more functions that may manipulate the data of the data object. For example, a data object may include the functions or methods of an object in a software application implemented with an object-oriented programming language. Further, as used herein, the term “physical component” may include a physical element or sub-component of a machine or other apparatus. A physical component may include multiple sub-components, and the term “physical component” may be equally applicable to a sub-component unless otherwise specified. Additionally, as used herein, many occurrences of “function” may include a function represented by a block in a functional block diagram (FBD), a functional flow block diagram (FFBD), or other similar flow diagram. A function may include a finite, discrete action to be accomplished by a system's elements. Further, a function may include an iterative action with one or more specific exit criteria that may end the function. Additionally, a function may include a high-level function, a sub-function, or other type of function applicable to a visual mapping diagram. Furthermore, a function may include one or more inputs. An input may include the output of another function, a piece of data, an action, or other information that can serve as the input to a function. Additionally, a function may include one or more outputs. An output may include a data element (described below), an action, or other information sent from the function. The output may act as the input to one or more other functions.

As used herein, a “data vessel” may include a container of data. A data vessel may take on a variety of forms, including a document (including a physical paper document or a file on a computer), email, notes (either on paper or in a file on a computer), drawings, computer-assisted drawing (CAD) files, or other types of data containers. Further, a data vessel may include a digital data vessel. In at least some embodiments, a digital data vessel may include a data vessel that stores data in a predetermined format. The predetermined format may include storage in a database, a computer file of a certain file format, a Product Lifecycle Management (PLM) software system, or other format. Examples of a data vessel that is not a digital data vessel may include a physical paper file, paper notes, a vocal conversation, or other data vessel format. As used herein, a “data element” may include a discrete piece of information. Examples of a data element include the name of a physical component, the physical location of a physical component, the dimensions of a component, or other information about a component. In some embodiments, a data element may include data indirectly related to the physical component, such as a project due date, material costs, a meeting date or time, or other lifecycle data. The term “data element instance” may include a specific occurrence of a data element, and the data element may appear in multiple occurrences simultaneously. A data element instance may be stored or otherwise included in a data vessel. As an example, a data element may include the dimensions of the physical component, and multiple instances of the dimensions may be present in an email data vessel and a database data vessel.

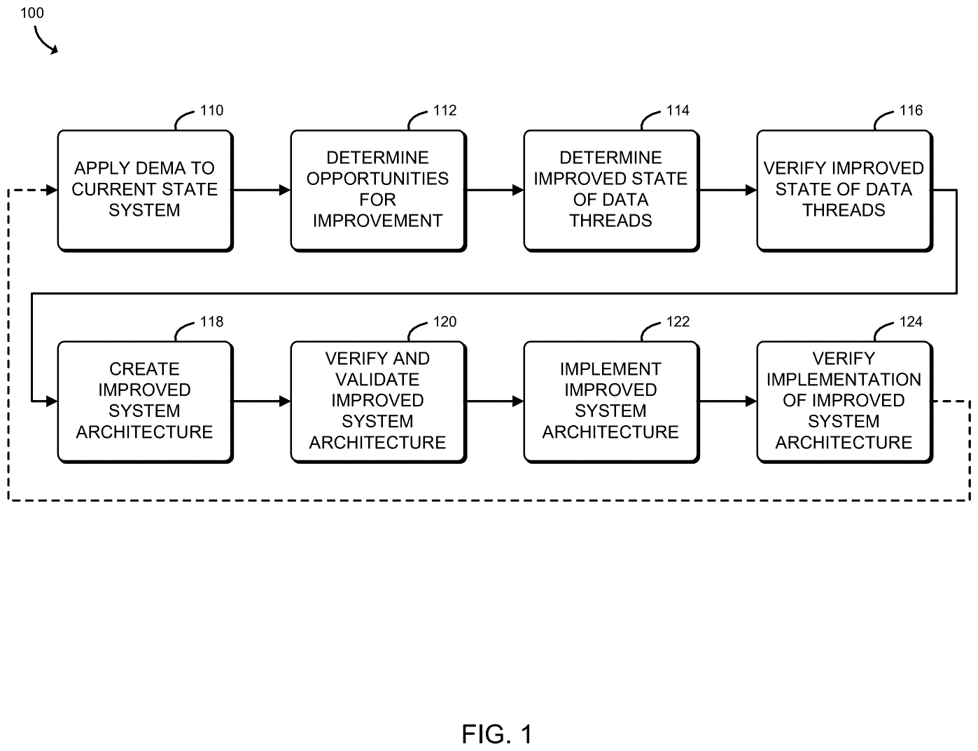

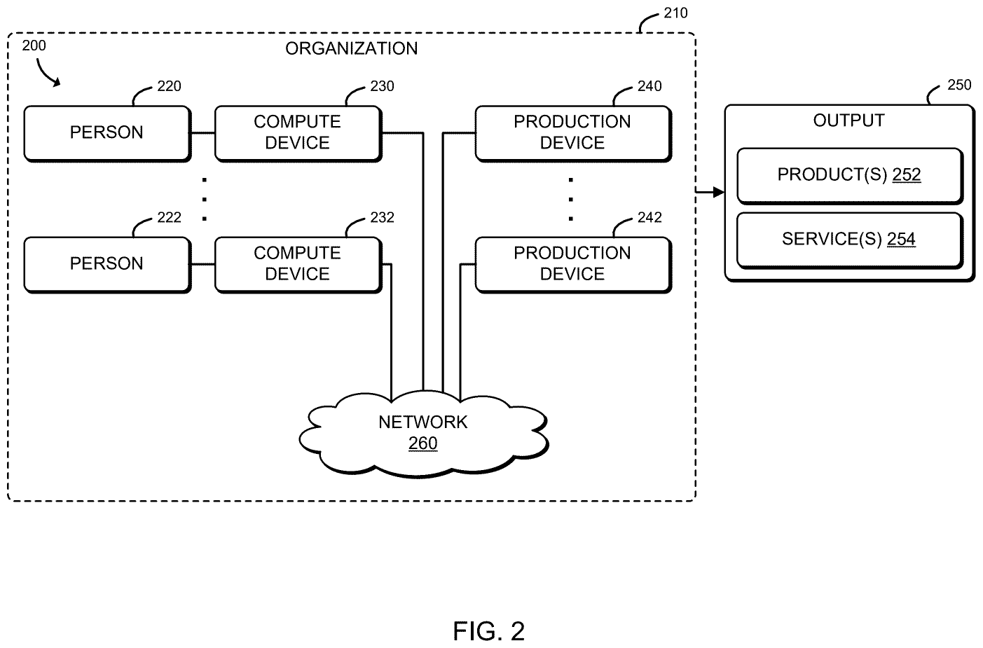

Referring now to FIGS. 1 and 2, a diagram of a methodology 100 for providing continuous improvement of a system 200 (e.g., to ultimately improve an output 250 of the system 200) includes a series of operations 110, 112, 114, 116, 118, 120, 122, 124 that may be executed in a loop. The methodology prioritizes identifying and improving key data threads of the system 200 based on data element reuse and metrics for improvement. As such, the methodology enables incremental steps to be taken towards realizing ideal data threads (e.g., also referred to herein as data flows) without requiring an organization 210 (e.g., an organization that implements the system 200) to invest significant up-front resources to overhaul the entirety of all data threads within the system 200. As indicated in FIG. 2, the system 200 may include multiple people 220, 222, each of whom may operate a corresponding compute device 230, 232 to produce, view, edit, transmit, and receive data used in the creation of output 250, which, in the illustrative embodiment, includes one or more products 252 (e.g., physical products) and may include one or more services 254 (e.g., maintenance services for the products 252, delivery services for the products 252, subscription-based access to the products 252 (e.g., software as a service, platform as a service, infrastructure as a service), and/or other services). Further, the system 200 may include a set of production devices 240, 242 such as machines (e.g., presses, stamping machines, saws, welding machines, conveyors, industrial ovens, etc.), robots (e.g., manipulator arms), sensors (e.g., heat sensors, pressure sensors, photoelectric sensors, etc.), and/or other devices capable of performing functions in accordance with the data threads of the system 200 (e.g., utilizing data provided via a data thread, creating data to be provided for use in other functions of the system 200 via a data thread) to produce the output 250.

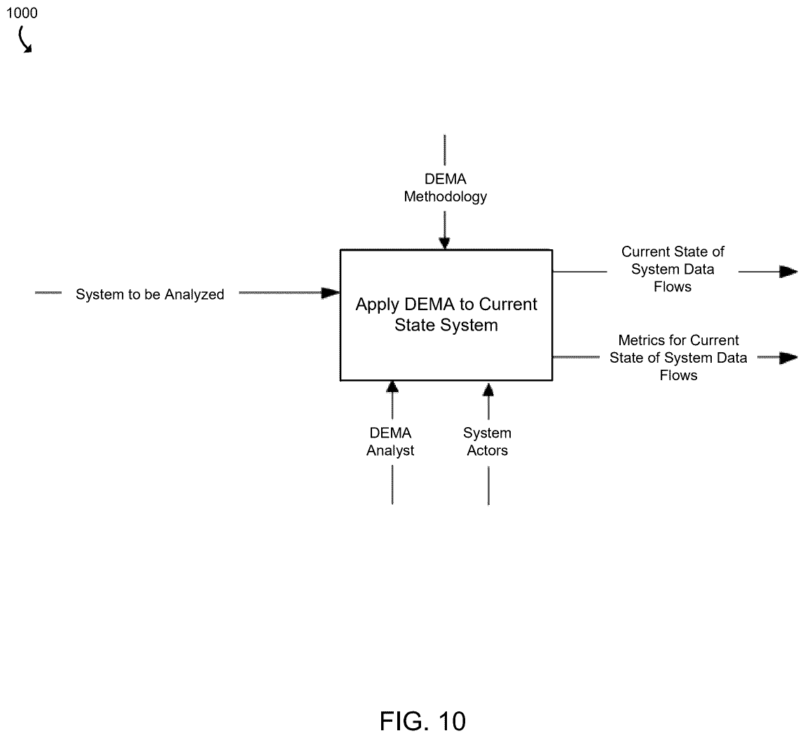

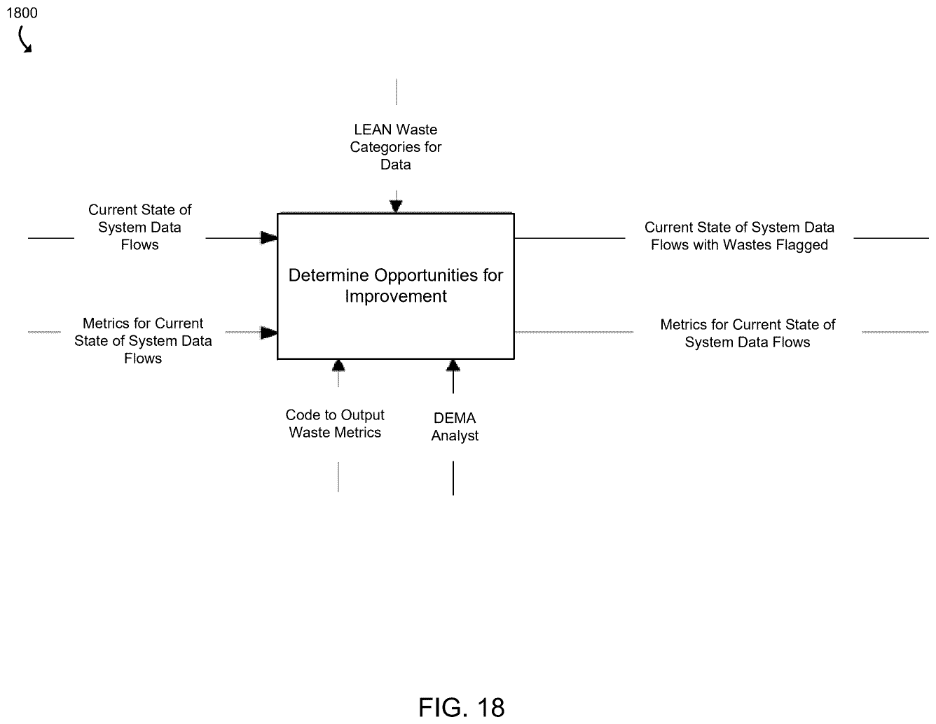

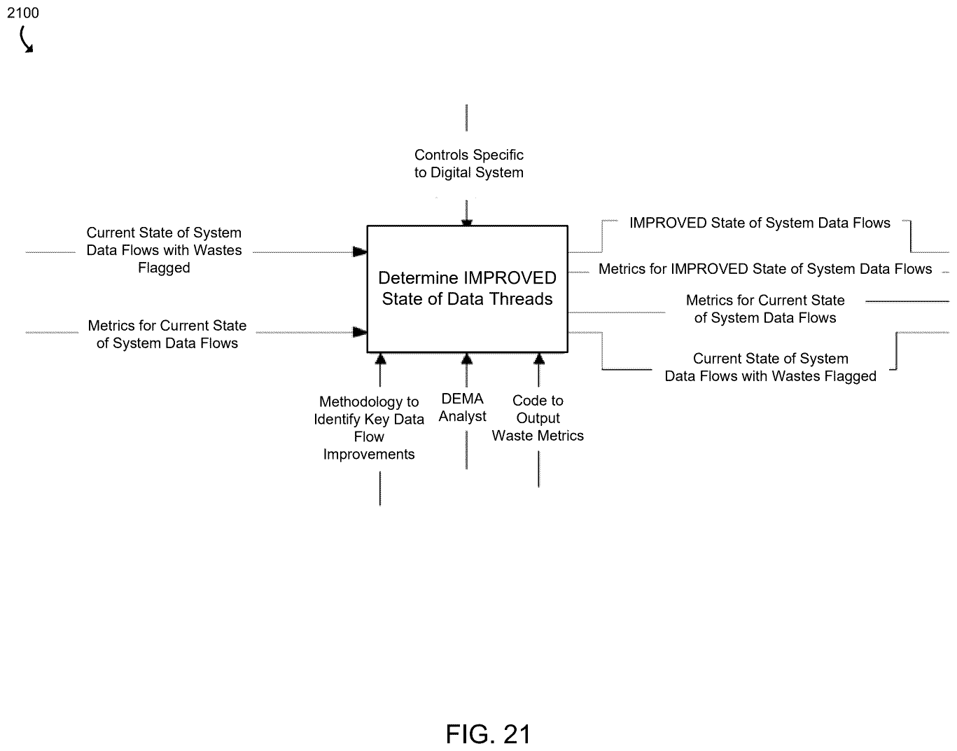

As described in more detail herein, the methodology illustrated in FIG. 1 includes an initial operation 110 to apply data element mapping and analysis (DEMA) to the system 200 in its current state. In the operation 110, which is shown in more detail in the diagram 1000 of FIG. 10, DEMA is applied to the system to be analyzed. The operation 110 is constrained by the DEMA methodology and enabled by a DEMA analyst and system actors. The system to be analyzed is an input, and the outputs are the captured current state of the system's data flows (Functional, Data Vessel, and Data Element Level Views) and metrics for the current state of the system data flows (if available). Further, the methodology includes the operation 112 of determining opportunities for improvement (e.g., based on the results of the DEMA analysis from the operation 110). In the operation 112, which is shown in more detail in the diagram 1800 of FIG. 18, a Data Element Level View spread sheet or similar table data structure is inputted into a set of sub operations to identify waste categories within the current state data element flows and flag them within the data flows. A DEMA analyst, in at least some embodiments, may conduct the operation 112. The outputs of the operation 112, in the illustrative embodiment, are the current state of data flows with flagged wastes and the current state metrics. Subsequently, the methodology includes determining an improved state of data threads of the system in the operation 114. A detailed diagram 2100 of the operation 114 is shown in FIG. 21. In at least some embodiments, the wastes flagged in the current state of data flows are used to determine what changes should be made to improve the data threads. The metrics of improvement, the controls specific to the digital system to be implemented (PLM, SysML, etc.), and a methodology to determine key data flow improvements are used to create the improved state of system data flows. In at least some embodiments, a DEMA analyst conducts the operation 114. Importantly, in at least some embodiments, the improved state of the data threads is based on adjusting a prioritized subset of the data threads of the system 200, rather than all of the data threads. As described in more detail herein, the prioritization is based on a determination of which data threads, if adjusted, will provide the greatest amount of improvement (e.g., reducing waste and improving efficiency and/or quality of the operations leading to the output 250 of the system 200).

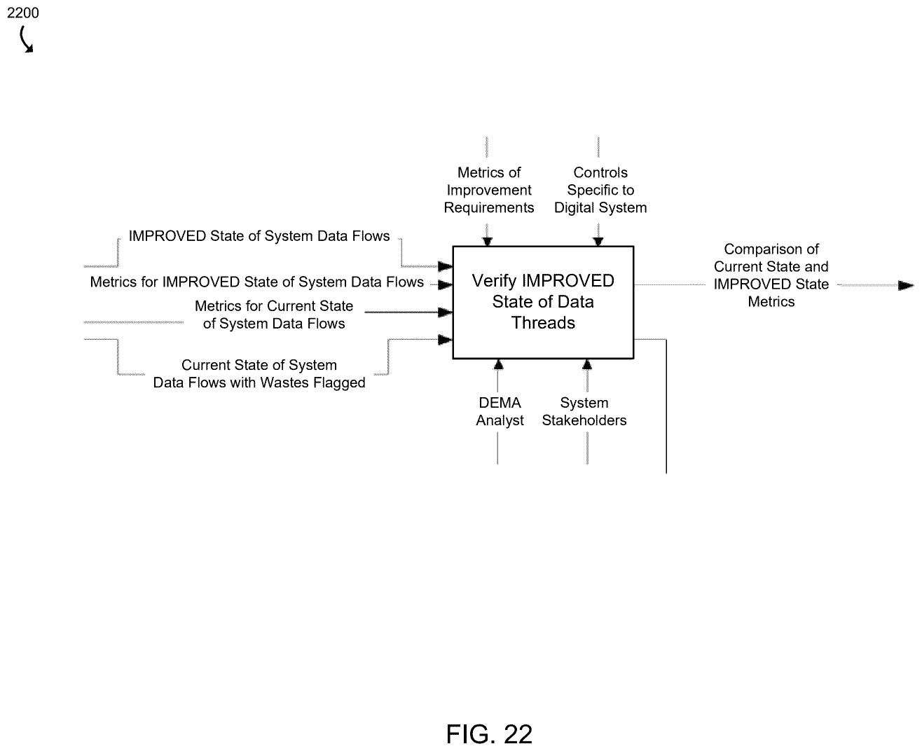

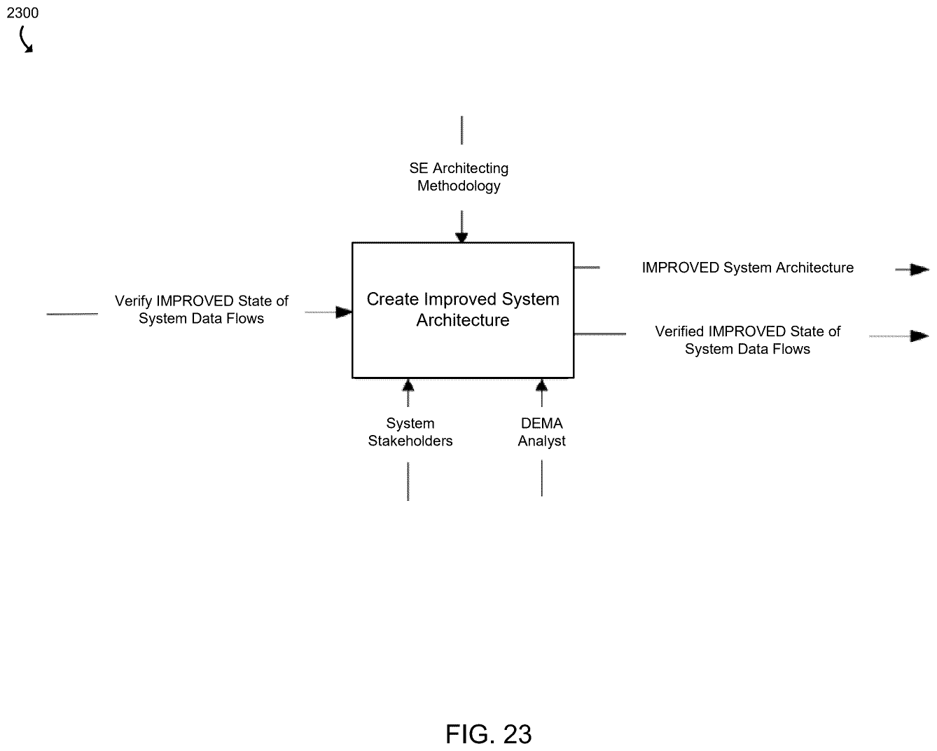

Afterwards, the methodology includes verifying the improved state of the data threads in the operation 116. A detailed diagram 2200 of the operation 116 is shown in FIG. 22. In the operation 116, a DEMA analyst may present the improved state and metrics of the system data flows to system stakeholders. The operation 116 may further include comparing the current and improved data flows to ensure that the improved metrics meet the requirements (e.g., of the system stakeholders) for improvements. That determination may include determinations of whether the improvements provide sufficient cost savings and/or improved traceability, to justify the implementation of the improved state, from the perspective of the quantity of resources that will be consumed to perform the implementation. The operation 116 may also include evaluating the improved state of data flows to verify that the improved state follows the controls of the digital system to be implemented (e.g., to determine whether the improved state is feasible). Further, the methodology includes creating an improved system architecture (e.g., based on the improved data threads), in the operation 118. A detailed diagram 2300 of the operation 118 is shown in FIG. 23. In the operation 118, the verified improved state of system data flows is used to create an architecture of the improved system. The architecture is used directly to implement the improved system and, in the illustrative embodiment, is created using systems engineering (SE) architecting methodology. In at least some embodiments, system stakeholders and the DEMA analyst may perform the operation 118 together.

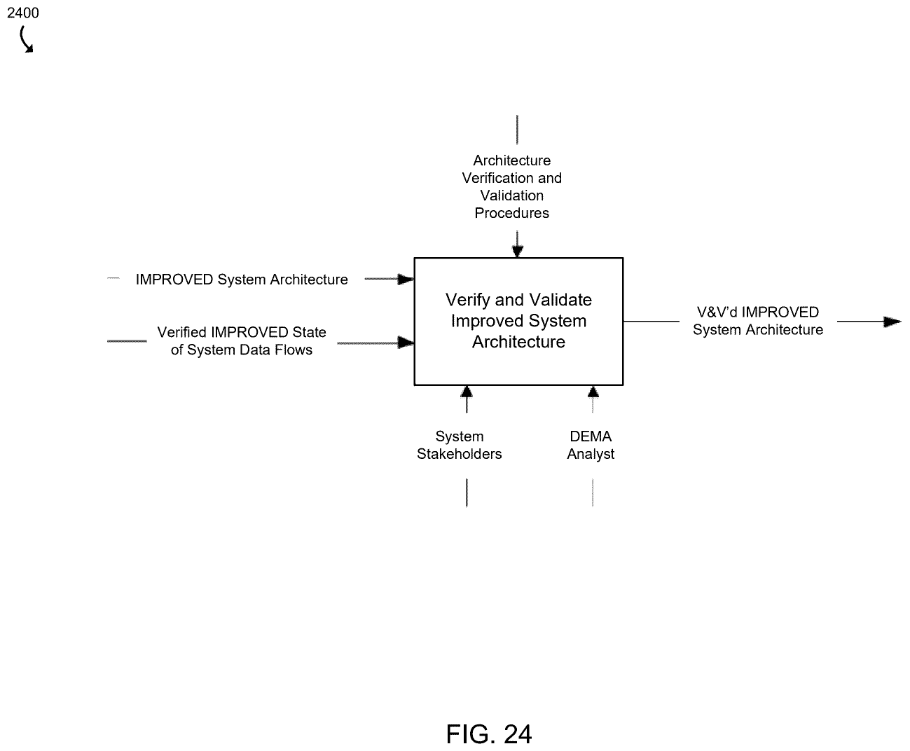

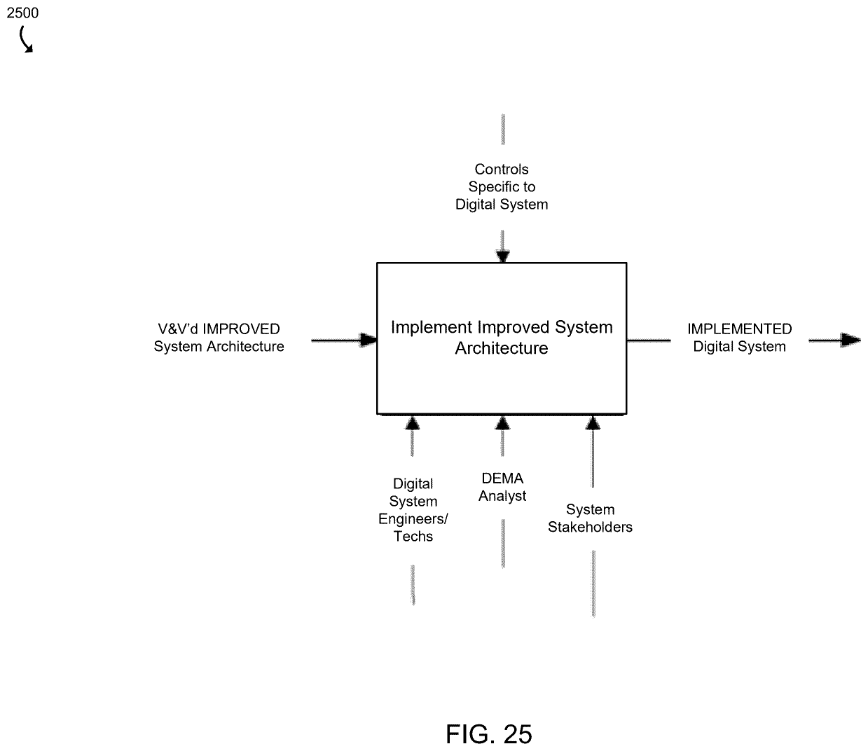

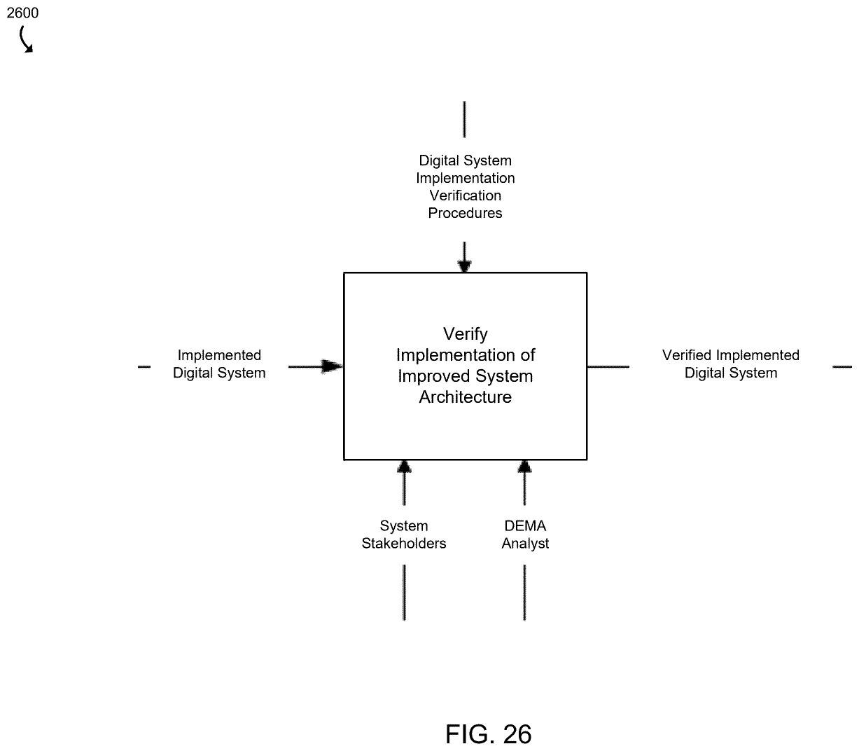

Subsequently, the methodology includes verifying and validating the improved system architecture, in the operation 120. A detailed diagram 2400 of the operation 120 is shown in FIG. 24. In the operation 120, the improved system architecture may be verified and validated by system stakeholders and the DEMA analyst. Performance of the operation 120 ensures that the architecture has been created correctly and that the architecture accomplishes its intended purpose. Afterwards, the methodology includes implementing the improved system architecture, in the operation 122. A detailed diagram 2500 of the operation 122 is shown in FIG. 25. In the operation 122, the verified and validated improved system architecture is implemented to create the digital system. In at least some embodiments, engineers and/or technicians for the digital system (e.g., using project lifecycle management (PLM) and a language for data exchanges and a tool for creating visual mapping (e.g., SysML)) may implement the architecture. The DEMA analyst and system stakeholders may provide assistance for the operations 122. Further, the methodology involves verifying implementation of the improved system architecture, in the operation 124. A detailed diagram 2600 of the operation 124 is shown in FIG. 26. In the operation 124, system stakeholders and the DEMA analyst may verify that the improved system architecture has been implemented correctly From there, the verified implemented digital system can be left alone, or the continuous improvement methodology can start back at the operation 110 for further improvement. That is, and as indicated by the dashed line leading from the operation 124 to the operation 110, the organization 210 may iteratively and continually repeat the operations 110, 112, 114, 116, 118, 120, 122, 124, adjusting the data threads of the system 200 over time according to their prioritization. As such, the methodology enables the organization 210 to implement the most impactful adjustments to the data threads up front and, over time and as the organization's available resources allow, refine the data threads to obtain additional efficiencies. In at least some embodiments, one or more operations of the methods described herein may be performed in whole or in part by a compute device (e.g., the operations of a DEMA analyst, a stakeholder, an engineer, or other role may be executed by a compute device), utilizing data mining, digital twins, artificial intelligence (e.g., machine learning, utilizing large language models, artificial neural networks, decision tree ensembles of weak learners combined into strong learners, etc.), and/or rules based algorithms. The methods may be applied to cyber-physical systems, lifecycles for sustainability, cyber-security, healthcare, and/or supply chains to name a few.

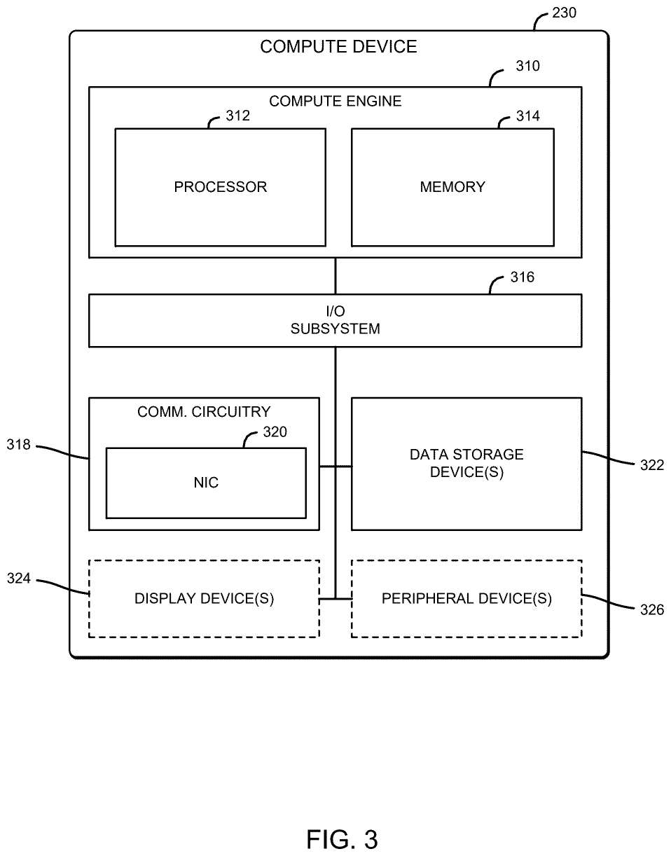

Referring now to FIG. 3, an illustrative embodiment of a compute device of the system 200 (e.g., the compute device 230) includes a compute engine 310, an input/output (I/O) subsystem 316, communication circuitry 318, and one or more data storage devices 322. In some embodiments, the compute device 230 may include one or more display devices 324 and/or one or more peripheral devices 326 (e.g., a mouse, a physical keyboard, etc.). In some embodiments, one or more of the illustrative components may be incorporated in, or otherwise form a portion of, another component. The compute engine 310 may be embodied as any type of device or collection of devices capable of performing various compute functions described below. In some embodiments, the compute engine 310 may be embodied as a single device such as an integrated circuit, an embedded system, a field-programmable gate array (FPGA), a system-on-a-chip (SOC), or other integrated system or device. Additionally, in the illustrative embodiment, the compute engine 310 includes or is embodied as a processor 312 and a memory 314. The processor 312 may be embodied as any type of processor capable of performing the functions described herein. For example, the processor 312 may be embodied as a single or multi-core processor(s), a microcontroller, or other processor or processing/controlling circuit. In some embodiments, the processor 312 may be embodied as, include, or be coupled to an FPGA, an application specific integrated circuit (ASIC), reconfigurable hardware or hardware circuitry, or other specialized hardware to facilitate performance of the functions described herein.

In embodiments, the processor 312 is capable of receiving, e.g., from the memory 314 or via the I/O subsystem 316, a set of instructions which when executed by the processor 312 cause the compute device 230 to perform one or more operations described herein. In embodiments, the processor 312 is further capable of receiving, e.g., from the memory 314 or via the I/O subsystem 316, one or more signals from external sources, e.g., from the peripheral devices 326 or via the communication circuitry 318 from an external compute device, external source, or external network. As one will appreciate, a signal may contain encoded instructions and/or information. In embodiments, once received, such a signal may first be stored, e.g., in the memory 314 or in the data storage device(s) 322, thereby allowing for a time delay in the receipt by the processor 312 before the processor 312 operates on a received signal. Likewise, the processor 312 may generate one or more output signals, which may be transmitted to an external device, e.g., an external memory or an external compute engine via the communication circuitry 318 or, e.g., to one or more display devices 324. In some embodiments, a signal may be subjected to a time shift in order to delay the signal. For example, a signal may be stored on one or more storage devices 322 to allow for a time shift prior to transmitting the signal to an external device. One will appreciate that the form of a particular signal will be determined by the particular encoding a signal is subject to at any point in its transmission (e.g., a signal stored will have a different encoding than a signal in transit, or, e.g., an analog signal will differ in form from a digital version of the signal prior to an analog-to-digital (A/D) conversion).

The main memory 314 may be embodied as any type of volatile (e.g., dynamic random access memory (DRAM), etc.) or non-volatile memory or data storage capable of performing the functions described herein. Volatile memory may be a storage medium that requires power to maintain the state of data stored by the medium. In some embodiments, all or a portion of the main memory 314 may be integrated into the processor 312. In operation, the main memory 314 may store various software and data used during operation such as applications, libraries, and drivers.

The compute engine 310 is communicatively coupled to other components of the compute device 230 via the I/O subsystem 316, which may be embodied as circuitry and/or components to facilitate input/output operations with the compute engine 310 (e.g., with the processor 312 and the main memory 314) and other components of the compute device 230. For example, the I/O subsystem 316 may be embodied as, or otherwise include, memory controller hubs, input/output control hubs, integrated sensor hubs, firmware devices, communication links (e.g., point-to-point links, bus links, wires, cables, light guides, printed circuit board traces, etc.), and/or other components and subsystems to facilitate the input/output operations. In some embodiments, the I/O subsystem 316 may form a portion of a system-on-a-chip (SoC) and be incorporated, along with one or more of the processor 312, the main memory 314, and other components of the compute device 230, into the compute engine 310.

The communication circuitry 318 may be embodied as any communication circuit, device, or collection thereof, capable of enabling communications over a network between the compute device 230 and another device (e.g., a device 232, 240, 242, etc.). The communication circuitry 318 may be configured to use any one or more communication technology (e.g., wired or wireless communications) and associated protocols (e.g., Ethernet, Wi-Fi®, WiMAX, Bluetooth®, etc.) to effect such communication.

The illustrative communication circuitry 318 includes a network interface controller (NIC) 320. The NIC 320 may be embodied as one or more add-in-boards, daughter cards, network interface cards, controller chips, chipsets, or other devices that may be used by the compute device 230 to connect with another compute device (e.g., a device 232, 240, 242, etc.). In some embodiments, the NIC 320 may be embodied as part of a system-on-a-chip (SoC) that includes one or more processors, or included on a multichip package that also contains one or more processors. In some embodiments, the NIC 320 may include a local processor (not shown) and/or a local memory (not shown) that are both local to the NIC 320. Additionally or alternatively, in such embodiments, the local memory of the NIC 320 may be integrated into one or more components of the compute device 230 at the board level, socket level, chip level, and/or other levels.

Each data storage device 322, may be embodied as any type of device configured for short-term or long-term storage of data such as, for example, memory devices and circuits, memory cards, hard disk drives, solid-state drives, or other data storage device. Each data storage device 322 may include a system partition that stores data and firmware code for the data storage device 322 and one or more operating system partitions that store data files and executables for operating systems.

Each display device 324 may be embodied as any device or circuitry (e.g., a liquid crystal display (LCD), a light emitting diode (LED) display, a cathode ray tube (CRT) display, etc.) configured to display visual information (e.g., text, graphics, etc.) to a user. In some embodiments, a display device 324 may be embodied as a touch screen (e.g., a screen incorporating resistive touchscreen sensors, capacitive touchscreen sensors, surface acoustic wave (SAW) touchscreen sensors, infrared touchscreen sensors, optical imaging touchscreen sensors, acoustic touchscreen sensors, and/or other type of touchscreen sensors) to detect selections of on-screen user interface elements or gestures from a user.

In the illustrative embodiment, the components of the compute device 230 are housed in a single unit. However, in other embodiments, the components may be in separate housings, in separate racks of a data center, and/or spread across multiple data centers or other facilities. The devices 232, 240, 242 may have components similar to those described above with reference to the compute device 230. The description of those components of the compute device 230 is equally applicable to the description of components of the devices 232, 240, 242. Further, it should be appreciated that any of the devices 232, 240, 242 may include other components, sub-components, and devices commonly found in a computing device, which are not discussed above in reference to the compute device 230 and not discussed herein for clarity of the description.

In the illustrative embodiment, the compute devices 230, 232, 240, 242 are in communication via a network 260, which may be embodied as any type of wired or wireless communication network, including global networks (e.g., the internet), wide area networks (WANs), local area networks (LANs), digital subscriber line (DSL) networks, cable networks (e.g., coaxial networks, fiber networks, etc.), cellular networks (e.g., Global System for Mobile Communications (GSM), Long Term Evolution (LTE), Worldwide Interoperability for Microwave Access (WiMAX), 3G, 4G, 5G, etc.), a radio area network (RAN), or any combination thereof.

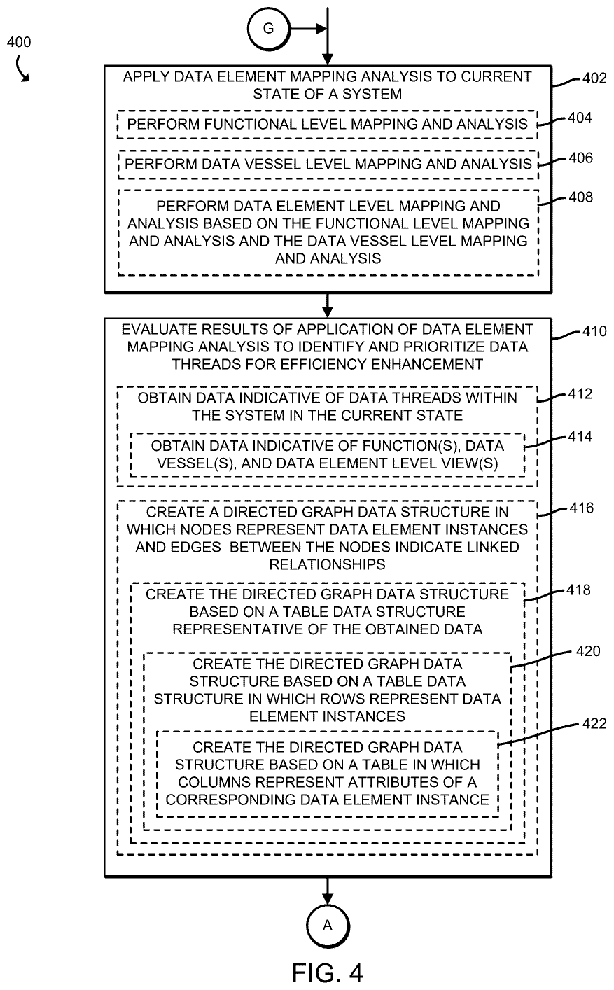

Referring now to FIG. 4, a method 400, corresponding to the methodology 100 of FIG. 1, for providing continuous improvement for digital engineering (e.g., to improve an output of a system, such as the system 200) begins, in the illustrative embodiment, with block 402 which includes applying a data element mapping analysis (DEMA) to a current state of the system (e.g., the system 200). The block 402 corresponds with the operation 110 of FIG. 1. A more detailed diagram 1000 of the operation 110 is shown in FIG. 10. As indicated in block 404, in performing the DEMA analysis, the method 400, in the illustrative embodiment, includes performing functional level mapping and analysis. Further, in the illustrative embodiment, the method 400 includes performing a data vessel level mapping and analysis, as indicated in block 406. Additionally, the method 400, in the illustrative embodiment, includes performing the data element level mapping and analysis based on (e.g., after obtaining the results of) the functional level mapping and analysis (e.g., from block 404) and the data vessel level mapping and analysis (e.g., from block 406), as indicated in block 408. The operations of the data element mapping and analysis are described in detail in U.S. Provisional Application No. 63/290,805, entitled “DATA ELEMENT MAPPING AND ANALYSIS (DEMA)”, filed Dec. 17, 2021, and U.S. patent application Ser. No. 18/067,888, entitled “IMPROVING PHYSICAL COMPONENTS USING DATA ELEMENT MAPPING AND ANALYSIS”, filed Dec. 19, 2022, the contents of which are incorporated herein by reference in their entirety.

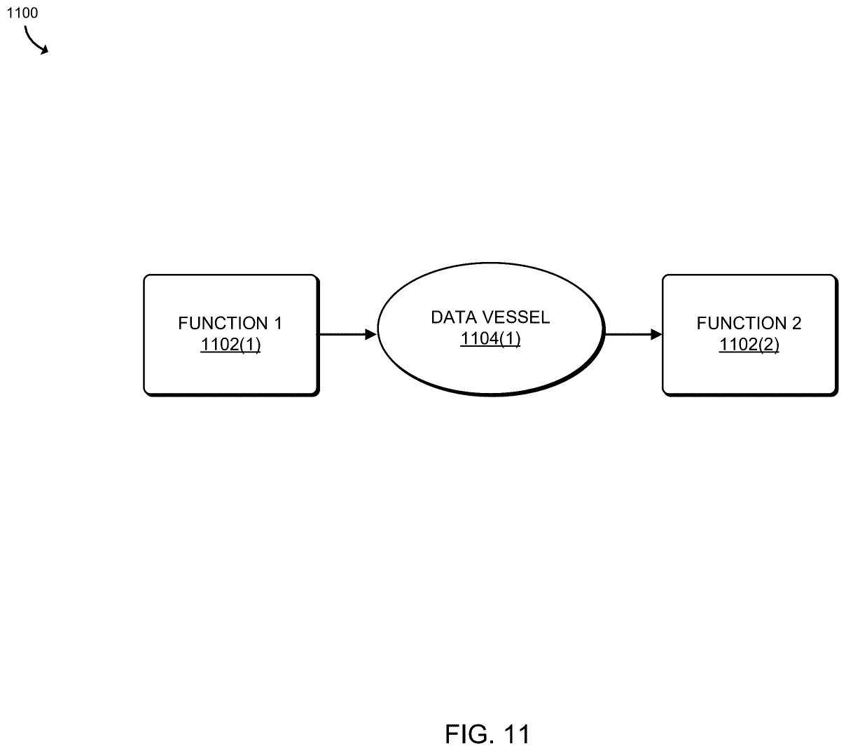

FIG. 11 shows a visual representation of a system 1100 that includes function data objects 1102(1)-(2) and a data vessel data object 1104(1). As can be seen from FIG. 11, the first function data object 1102(1) may connect to the data vessel data object 1104(1). The data vessel data object 1104(1) may, in turn, connect to the second function data object 1102(2). Thus, the system 1100 of FIG. may represent that a data element flows from a first function (corresponding to the first function data object 1102(1)) to a second function (corresponding to the second function data object 1102(2)) and that the data element is stored in a data vessel (corresponding to the data vessel data object 1104(1)) during the flow. In one embodiment, each function data object 1102 may correspond to a function in a visual mapping diagram. A visual mapping diagram may include a FBD, FFBD, an Integration Definition for Process Modelling (IDEF0) diagram, a DeMarco data flow diagram, or other visual mapping diagram. In some embodiments, each data vessel data object 1104 may correspond to a data vessel. The corresponding data vessel data object 1104 may include a digital format indicator, which may include data indicating whether the corresponding data vessel is a digital data vessel.

In one embodiment, a function data object 1102(1) or a data vessel data object 1104(1) may include data referencing another function data object 1102(2) or another data vessel data object 1104(2). The data referencing another function data object 1102(2) or data vessel data object 1104(2) may indicate that the function corresponding to the function data object 1102(1) or the data vessel corresponding to the data vessel data object 1104(1) may send a data element to another function (corresponding to the other function data object 1102(2)) or another data vessel (corresponding to the other data vessel data object 1104(2)). In some embodiments, data referencing data may include an identifier of the other function data object 1102(2) or data vessel 1104(2), a logical pointer (e.g., a pointer in an object-oriented programming language), or other type of data capable of referencing the other function data object 1102(2) or data vessel 1104(2). As an example, a design engineer, as part of a design development function, may determine the dimensions of the physical component. The design engineer may then email the dimensions to a manufacturing engineer. The manufacturing engineer, as part of a testing function, may produce a sample of the physical component using the dimensions. In this example, the design development function and the testing function are functions, the email is a data vessel, and the dimensions of the physical component are the data element. The inclusion of the dimensions in the email by the design engineer may include a connection from the design development function to the email data vessel, and the use of the dimensions from the email in the testing function may include a connection from the email data vessel to the testing function.

Continuing the example, a first data storage may store a design development function data object 1102(1), a testing function data object 1102(2), and an email data vessel data object 1104. The design development function data object 1102(1) may correspond with the design development function. The testing function data object 1102(2) may correspond with the testing function. The email data vessel data object 1104 may correspond with the email. The design development function data object 1102(1) may include data referencing the email data vessel data object 1104, which may correspond to the dimensions being sent via an email as part of the design development function. The email data vessel data object 1104 may include data referencing the testing function data object 1102(2), which may correspond to the dimensions being retrieved from the email as part of the testing function. In some embodiments, the system 1100 may include any number of function data objects 1102, data vessel data objects 1104, or connections between such data objects 1102, 1104. Furthermore, in some embodiments, a single function data object 1102 may include multiple references to different data vessel data objects 1104. This may correspond to (1) a single function sending the same data element to multiple different data vessels, (2) a single function sending different data elements to multiple different data vessels, or (3) a combination of the two. Similarly, a single data vessel may include multiple references to different function data objects 1102, which may correspond to (1) a single data vessel sending the same data element to multiple different functions, (2) a single data vessel sending different data elements to multiple different functions, or (3) a combination of the two. In certain embodiments, a single function data object 1102 may include multiple references to the same data vessel data object 1104, which may correspond to a single function sending different data elements to the same data vessel. Similarly, a single data vessel data object 1104 may include multiple references to the same function data object 1102, which may correspond to a single data vessel sending different data elements to the same function.

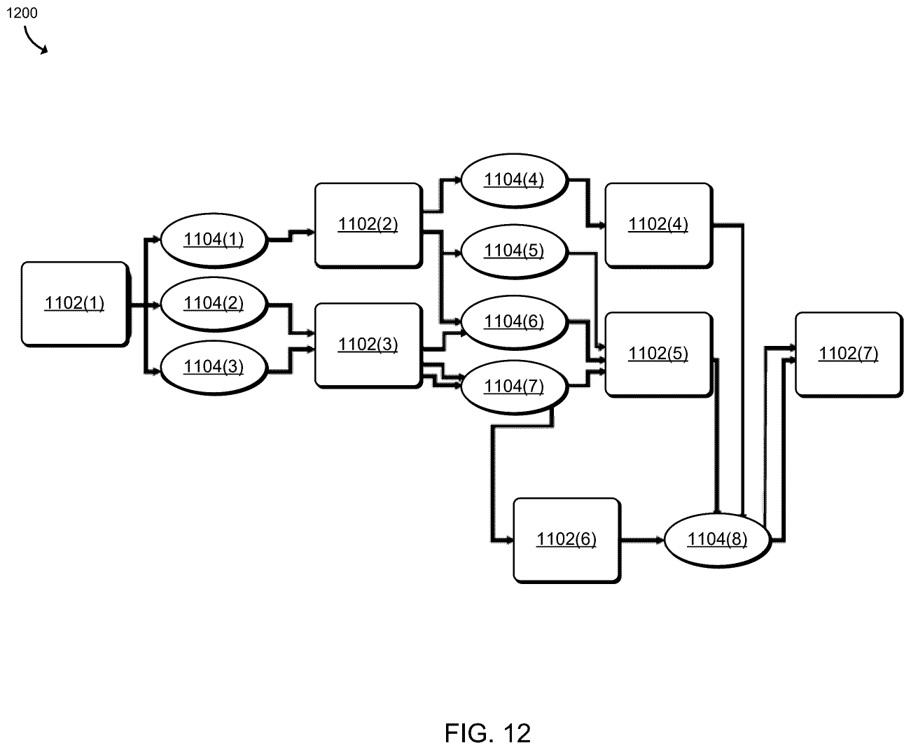

FIG. 12 shows one example of a system 1200 more complex than that of FIG. 11. As can be seen from FIG. 12, the system 1200 may include multiple function data objects 1102(1)-(7), multiple data vessel data objects 1104(1)-(8), and the data objects 1102, 1104 being connected via the various reference data. As also can be seen from FIG. 12, a single connection may connect from a single function data object 1102 to multiple data vessel data objects 1104 (e.g., the connection from function data object 1102(1) to data vessel data objects 1104(1)-(3)). This may represent the same data element being sent to different data vessels. Multiple connections may exist from a single function data object 1102 to a single data vessel object 1104 (e.g., the connections from function data object 1102(3) to data vessel data object 1104(7)). This may represent different data elements being sent from the same function with the same data vessel. Similar connections may occur from data vessel data objects 1104 to function data objects 1102.

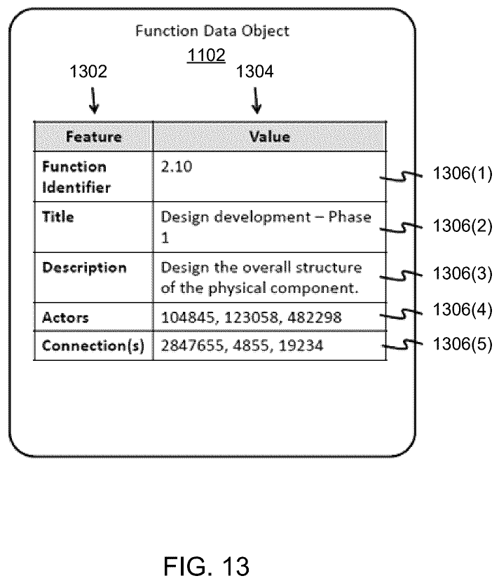

Further details regarding each of the function data objects 1102 and data vessel data objects 1104 are now discussed. FIG. 13 shows one embodiment of a function data object 1102. As discussed above, a function data object 1102 may correspond with a function in a FBD, FFBD, or other type of visual mapping. The function data object 1102 may include one or more features 1302 and their corresponding values 1304. A feature 1302 may include data associated with the function data object 1102. As can be seen from FIG. 13, a function data object 1102 may include a function identifier 1306(1). The function identifier 1306(1) may include a value 1304 that uniquely identifies the function from all other functions in the process for the physical component. The function identifier 1306(1) may include a number, a text string, or other type of data. The function data object 1102 may include a title 1306(2). The title 1306(2) may include a value 1304 that provides the title of the function that corresponds to the function data object 1102. The title 1306(2) may include a text string or other type of data.

In some embodiments, the function data object 1102 may include a description 1306(3). The description 1306(3) may include a value 1304 that describes the function that corresponds to the function data object 1102. The description 1306(3) may include a text string or other type of data. The function data object 1102 may include one or more actors 1306(4). The actors 1306(4) may include one or more values 1304 that identify a person, organization, computer system, or other entity (afterward, called an “actor”) that may provide some kind of action related to the function that corresponds to the function data object 1102. An actor may provide input to the function, perform one or more actions as part of the function, or perform other actions related to the function. The values 1304 of the actors 1306(4) may include identifying numbers (e.g., as depicted in FIG. 13), the actors' names, or other type of information that can identify the actors. In some embodiments, the function data object 1102 may include one or more references to one or more data vessel data objects. The one or more references may include one or more connections 1306(5). The connections 1306(5) may include one or more values 1304 that identify one or more data vessel data objects 1104 that correspond to data vessels to which the corresponding function sends one or more data elements. The values 1304 of the connections 1306(5) may include numbers, text strings, or other data that identify the connected data vessel data objects 1104 (e.g., the data vessel identifier 1402(1), discussed below).

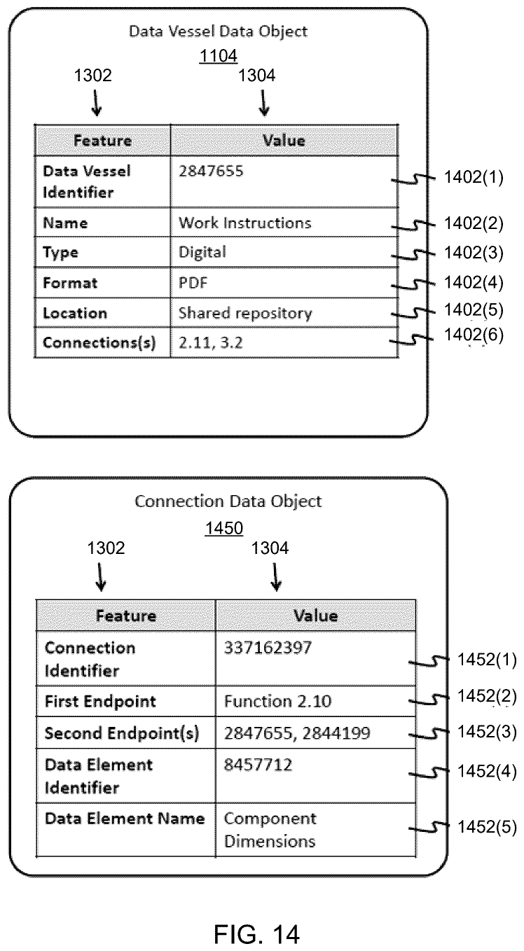

FIG. 14 shows an embodiment of a data vessel data object 1104. As discussed above, a data vessel data object 1104 may correspond with a data vessel in a data vessel mapping or other type of visual mapping. The data vessel data object 1104 may include one or more features 1302 and their corresponding values 1304. A feature 1302 may include data associated with the data vessel data object 1104. In some embodiments, the data vessel data object 1104 may include a data vessel identifier 1402(1). The data vessel identifier 1402(1) may include a feature 1302 whose value 1304 uniquely identifies the data vessel among the data vessels related to the process for the physical component. The data vessel identifier 1402(1) may include a number, a text string, or other type of data. The data vessel data object 1104 may include a name 1402(2). The name 1402(2) may include a feature 1302 whose value 1304 provides the name of the corresponding data vessel. The name 1402(2) may include a number, text string, or other type of data. The name 1402(2) may include a filename, the name of a physical document, the name of a database or portion of a database, the subject line of an email, a description of the data vessel (e.g., “personal notes taken by engineer,” “conversation between engineer and tester,” etc.), or other name-related data.

In some embodiments, the data vessel data object 1104 may include a type 1402(3). The type 1402(3) may include a feature 1302 whose value 1304 identifies whether the corresponding data vessel is a digital data vessel. The type 1402(3) may include a Boolean (e.g., “True” indicates that data vessel is a digital data vessel and “False” indicates that the data vessel is not a digital data vessel), a number (e.g., “1” indicates that data vessel is a digital data vessel and “0” indicates that the data vessel is not a digital data vessel), a text string, or other data. The data vessel data object 1104 may include a format 1402(4). The format 1402(4) may include a feature 1302 whose value 1304 provides the format that the corresponding data vessel is in. The format 1402(4) may include a number, text string, or other data. The format 1402(4) may include a file type (e.g., Portable Document Format (PDF), a Microsoft Word document, an email file, a CAD file, an image file, etc.). The format 1402(4) may include data indicating a paper document, a visual observation, a verbal conversation, or other format that the corresponding data vessel may be in. The data vessel data object 1104 may include a location 1402(5). The location 1402(5) may include a feature 1302 whose value 1304 may identify the location of the corresponding data vessel. The location 1402(5) may include a number, text string, or other data. The location 1402(5) may include a pathname (e.g., if the data vessel is a computer file), a uniform resource identifier (URI) or uniform resource location (URL) (e.g., if the data vessel is located on another device or on the Internet). The location 1402(5) may include an email directory, a shared repository, a database, physical storage, or other location.

In some embodiments, the data vessel data object 1104 may include one or more references to one or more function data objects 1102. The references may include one or more connections 1402(6). The connections 1402(6) may include one or more values 1304 that identify one or more function data objects 1102 that correspond to functions to which the corresponding data vessel sends one or more data elements. The values 1304 of the connections 1402(6) may include numbers, text strings, or other data that identify the connected function data objects 1102 (e.g., the function identifier 1306(1), discussed above). In some embodiments, the one or more references to one or more data vessel data objects 1104 or function data objects (e.g., the connections 1306(5) of the function data object 1102 or the connections 1402(6) of the data vessel data object 1104) may include a connection data object. The connection data object may include a data object that corresponds to a connection between a function and a data vessel. Thus, in some embodiments, instead of including references to function data objects 1102 or data vessel data objects 1104 directly in the connections 1306(5), 1402(6), the function data objects 1102 and data vessel data objects 1104 may include references to connection data objects, which in turn, may reference the connecting function data object(s) 1102 or data vessel data object(s) 1104.

FIG. 14 also shows an embodiment of a connection data object 1450. The connection data object 1450 may include one or more features 1302 and their corresponding values 1304. A feature 1302 may include data associated with the connection data object 1450. In some embodiments, the connection data object 1450 may include a connection identifier 1452(1). The connection identifier 1452(1) may include a feature 1302 whose value 1304 uniquely identifies the connection data object 1450 among the connection data objects 1450 associated with the process for the physical component. The connection identifier 1452(1) may include a number, text string, or other data. The connections 1306(5), 1402(6) of a function data object 1102 or data vessel data object 1104 may include a connection identifier 1452(1). In certain embodiments, the connection data object 1450 may include a first endpoint 1452(2). The first endpoint 1452(2) may include data indicating a function data object 1102 or a data vessel data object 1104 that corresponds to the function or data vessel that is the first endpoint of the corresponding connection. The first endpoint 1452(2) may include a function identifier 1306(1), a data vessel identifier 1402(1), or other data that can identify the connecting function data object 1102 or data vessel data object 1104. The first endpoint 1452(2) may identify the function or data vessel from which the data element travels.

In some embodiments, the connection data object 1450 may include one or more second endpoints 1452(3). The one or more second endpoints 1452(3) may include data indicating a function data object 1102 or a data vessel data object 1104 that corresponds to the function or data vessel that is the second endpoint of the corresponding connection. The second endpoint 1452(3) may include a function identifier 1306(1), a data vessel identifier 1402(1), or other data that can identify the connecting function data object 1102 or data vessel data object 1104. The second endpoint 1452(3) may identify the function or data vessel to which the data element travels. As can be seen from FIG. 14, in some embodiments, a connection data object 1450 may have multiple second endpoints 1452(3), which may indicate that the same piece of data is sent to multiple functions or data vessels. Similarly (although not shown in FIG. 14), in some embodiments, a connection data object 1450 may have multiple first endpoints 1452(2), which may indicate that the same piece of data is sent from multiple functions or data vessels.

The connection data object 1450 may include a data element identifier 1452(4). In some embodiments, a connection data object 1450 may correspond to a certain data element moving from one function to another through a data vessel. This data element can be identified via the data element identifier 1452(4) of a connection data object 1450. Multiple connection data objects 1450 may include the same data element identifier 1452(4), which may indicate that the same data element is present in different functions or data vessels throughout the process for the physical component. In some embodiments, the data element identifier 1452(4) may include a number, a text string, or other data. The connection data object 1450 may include a data element name 1452(5). The data element name 1452(5) may include a name of the data element identified by the data element identifier 1452(4). The data element name 1452(5) may include a number, a text string, or other data. In some embodiments, a function data object 1102 may correspond to a sensor of a manufacturing system for the physical component sensing a physical phenomenon related to the manufacturing of the physical component. The sensor may generate an output signal based on the sensed phenomenon. A data element may include the output signal, which may include data related to the physical component. The sensor may send the output signal data element to a data vessel. Another function may use the output signal data element.

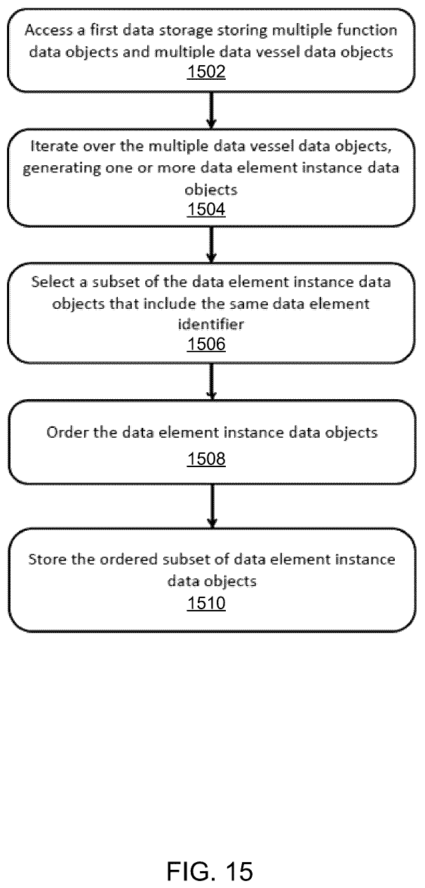

FIG. 15 shows an embodiment of a method 1500, which may, in some embodiments, may be used to ultimately improve the output of a system (e.g., one or more physical components (e.g., physical products) or services) using data element mapping and analysis. The method 1500 may include accessing a first data storage that stores multiple function data objects 1102 and multiple data vessel data objects 1104 (step 1502) Further, the method 1500 may include iterating over the multiple data vessel data objects 1104 and, for each data vessel data object, generating one or more data element instance data objects (step 1504). Additionally, the method 1500 may include selecting a subset of the data element instance data objects where the subset of data element instance data objects all include the same data element identifier (step 1506). The method 1500 may also include ordering the data element data objects (step 1508). The ordering may be based on the data element data objects' respective references to one or more other data element instance data objects. Additionally, the method 1500 may include storing the data element data objects in a second data storage (step 1510). Accessing the first data storage (step 1502) may include accessing function data objects 1102, data vessel data objects 1104, or connection data objects 1450 already in existence and already connected as discussed above. In some embodiments, iterating over the multiple data vessel data objects 1104 (step 1504) may include selecting each data vessel data object 1104 one at a time. The data vessel data objects 1104 may be selected in any order. During the iteration, for each data vessel data object 1104, the system may generate one or more data element instance data objects. Each data element data instance data object may correspond with an instance of a data element that is stored by the current data vessel.

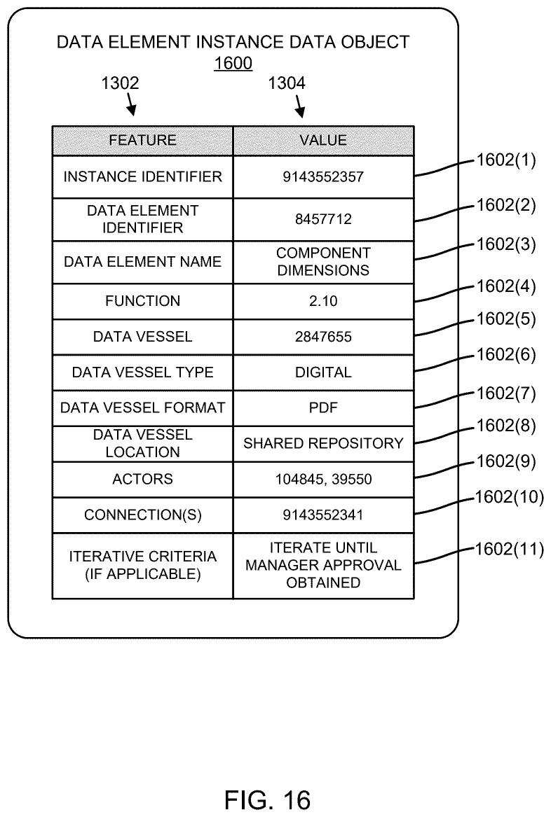

FIG. 16 shows an illustrative embodiment of a data element instance data object 1600. The data element instance data object 1600 may include one or more features 1302 and their corresponding values 1304. A feature 1302 may include data associated with the data element instance data object 1600. In some embodiments, the data element instance data object 1600 may include an instance identifier 1602(1). The instance identifier 1602(1) may uniquely identify the data element instance data object 1600 from all other data element instance data objects 1600 of the process. The instance identifier 1602(1) may include a number, a text string, or other data format. The data element instance data object 1600 may include a data element identifier 1602(2). The data element identifier 1602(2) may identify the data element associated with the data element instance data object 1600. The same data element may be stored in different data vessels during the process. Each instance of that data element may generate a different data element instance. Thus, the collection of all of the data element instances pertaining to the same data element may show the flow of the data element through various data vessels during the process. Accordingly, the data element identifier 1602(2) may identify the data element. The data element identifier 1602(2) may include a number, a text string, or data encoded in another data format.

In some embodiments, the data element instance data object may include a data element name 1602(3). The data element name 1602(3) may include the name of the data element identified by data element identifier 1602(2). The data element name 1602(3) may include a text string or data encoded in another data format. The data element instance data object 1600 may include a reference to a function 1602(4). The function reference 1602(4) may include a reference to a function data object 1102. The function data object 1102 may correspond to the function from which the data element was sent to the data vessel that corresponds to the data vessel data object 1104 currently selected in the iteration step. For example, in FIG. 12, if the data vessel data object 1104(1) is currently selected in the iteration step, then the function data object 1102(1) (corresponding to the function that sent the data element to the data vessel corresponding to data vessel data object 1104(1)) may be the function reference 1602(4). The function reference 1602(4) may include a function identifier 1306(1). The function reference 1602(4) may include a number, text string, logical connector, or data encoded in another data format.

The data element instance data object 1600 may include a reference to a data vessel 1602(5). The data vessel reference 1602(5) may include a reference to a data vessel data object 1104. The data vessel data object 1102 may correspond to the data vessel that stores the data element instance. The data vessel reference 1602(5) may include a reference to the data vessel data object currently selected in the iteration step. Further, the data vessel reference 1602(5) may include a data vessel identifier 1402(1). The data vessel reference 1602(5) may include a number, text string, logical connector, or data encoded in another data format. In some embodiments, the data element instance data object 1600 may include a data vessel type 1602(6), a data vessel format 1602(7), or a data vessel location 1602(8). These data may include, respectively, the type of the data vessel referenced by 1602(5), the format of the data vessel referenced by 1602(5), or the location of the data vessel referenced by 1602(5). This data may be identical to the type 1402(3), format 1402(4), or location 1402(5) of the data vessel data object 1104 referred to in 1602(5). In some embodiments, these data 1602(6)-(8) may not be stored in the data element instance data object.

In one or more embodiments, the data element instance data object 1600 may include one or more actors 1602(9). The one or more actors 1602(9) may include one or more values 1304 that identify an actor that may access the corresponding data element instance. An actor may create the data element instance, use the data element instance during the function specified by 1602(4), store the data element instance in the data vessel specified by 1602(5), or perform one or more other actions related to or with the data element instance. The values 1304 of the actors 1602(9) may include identifying numbers (e.g., as depicted in FIG. 16), the actors' names, or other type of information that can identify the actors. In some embodiments, the data element instance data object 1600 may include one or more connections 1602(10). The connections 1602(10) may include references to one or more other data element instance data objects 1600. A connection 1602(10) may correspond to a data element instance that directly precedes the data element instance corresponding to the current data element instance data object 1600. A connection 1602(10) may correspond to a data element instance that directly follows the data element instance corresponding to the current data element instance data object 1600. A connection 1602(10) may include an instance identifier 1602(1) of another data element instance data object 1600. Further, a connection 1602(10) may include a number, text string, logical connector, or data encoded in another data format. In some embodiments, the data element instance data object 1600 may include iterative criteria 1602(11), which may have a value that is indicative of conditions under which iteration should occur.

As an example, in FIG. 12, the data element of the physical component's dimensions may be sent from a first function (represented by the function data object 1102(1)) to a second function (represented the function data object 1102(2)) via a first data vessel (represented by the data vessel data object 1104(1)). Then, the physical component's dimensions may be sent from the second function to a third function (represented by the function data object 1102(4)) via a second data vessel (represented by the data vessel 1104(4)). The system may generate a first data element instance data object 1600(1) corresponding to the first data element instance (i.e., the physical component's dimensions being sent from the first function to the second function) and may generate a second data element instance data object 1600(2) corresponding to the second data element instance (i.e., the physical component's dimensions being sent from the second function to the third function). The second data element instance data object 1600(2) may include a connection 1602(10) that includes the instance identifier 1602(1) of the first data element instance data object 1600(1) to show that the first data element instance directly precedes the second data element instance.

In some embodiments, selecting the subset of the data element instance data objects 1600(step 1506) may include selecting the subset of the data element instance data objects 1600 with the same data element identifier 1602(2). As discussed previously, multiple data element instance data objects 1600 may include the same value 1304 for their data element identifier 1602(2). These data element instance data objects 1600 may show how the data element flows through the physical component's lifecycle. In some embodiments, an index may allow for the quick and efficient selection of the subset of data element instance data objects 1600. In some embodiments, selecting the subset may include selecting all of the data element instance data objects 1600 in the system 1100 with the same data element identifier 1602(2) or less than all of the data element instance data objects 1600 in the system 1100 with the same data element identifier 1602(2). Selecting the subset of data element instance data objects 1600 (step 1506) may include receiving an input that provides the value 1304 of the data element identifier 1602(2). The input may include user input on a UI (e.g., from a keyboard or mouse selection), data read from a file, data received from an external device, data received from another software program via an API, or other form of input. In some embodiments, the step of ordering the data element instance objects 1600 (step 1508) may include ordering the subset of data element instance data objects 1600 based on their respective connections 1602(10). The ordering of the data element instance data objects 1600 may show how the data element flows through the system. The ordering may result a branching in a tree structure or graph structure that includes the subset of data element instance data objects 1600.

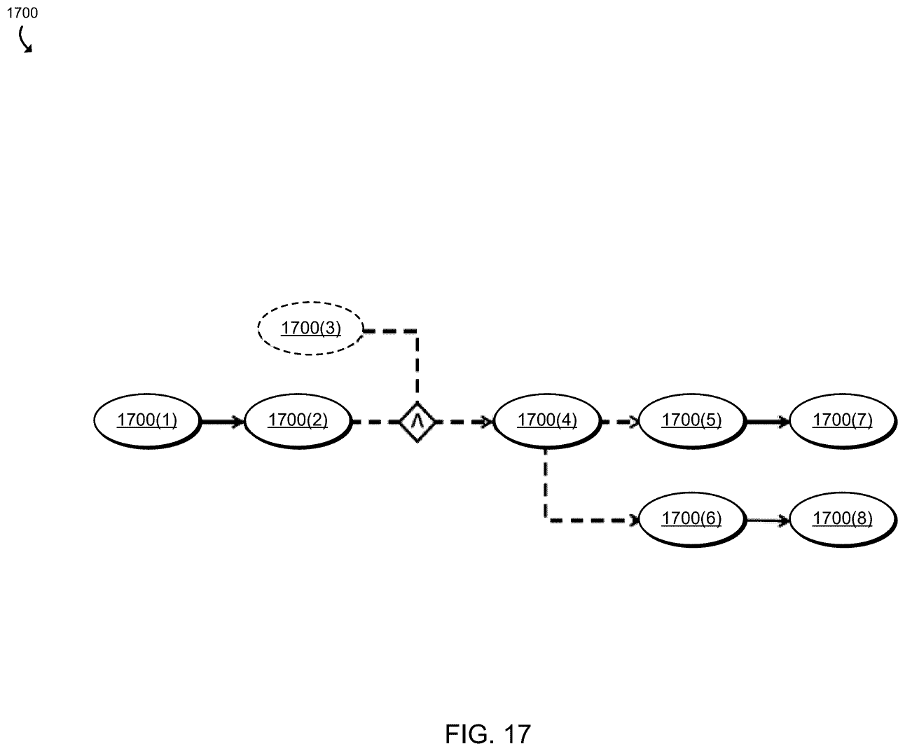

FIG. 17 shows an illustrative embodiment of a system 1700, which may include a visual representation of the ordering of the subset of data element instance data objects 1600(1)-(8). As can be seen from FIG. 17, the selected data element's flow may start at data element instance data object 1600(1). This may represent the data element being stored in a certain data vessel. The data element instance data object 1600(1) may be connected to data element instance data object 1600(2), which may represent the data element flowing to another data vessel. The data element instance data object 1600(2) may be connected to data element instance data object 1600(4), which may represent the data element flowing to another data vessel. The data element instance data object 1600(4) may be connected to data element instance data object 1600(5) and 1600(6), which may represent the data element flowing to two different data vessels. The flow may continue until the data element instance data objects 1600(7) and 1600(8) that do not include any further connections. In some embodiments, a different data element other than the one selected may be used with the selected data element during the process. For example, the selected data element may include the dimensions of the physical component. Another data element may include the location of an aperture on the physical component. In the system 1700 of FIG. 17, a data element instance data object 1600 corresponding to another data element other than the selected data element may be shown in dotted lines (e.g., the data element instance data object 1600(3)).

In some embodiments, multiple data element instance data objects 1600 may connect to a single data element instance data object 1600. For example, both the data element instance data objects 1600(2) and 1600(3) connect to the data element instance data object 1600(4). In FIG. 17, these data element instance data objects' 1600(2), 1600(3) connection to the data element instance data object 1600(4) includes a “A” symbol, which may indicate that the data elements are combined in some way or that the other data element has an effect on the data element. For example, the data element may include the dimensions of the physical component, and the other data element may include the location of an aperture on the physical component. The location of the aperture may affect the dimensions, thus, the location of the aperture may be used with the dimensions. In some embodiments, the connection may include a “V” symbol, which may indicate that the only one of the data elements are selected. For example, the data element may include dimensions. Two different data vessels may store the dimensions as part of different functions, and the two different instances of the dimensions may be different. The two data vessels may send the two different instances of the dimensions to the same function, and during the function, one of the instances may be selected (e.g., either by a user, software, or other actor).

A solid line between data element instance data objects 1600 may correspond with the data vessels that hold the instances of the data element being digitally connected and that the flow of the data element from one of the data vessels to the other data vessel is a digital flow. For example, the data element may include the dimensions of the physical component, the data vessel associated with data element instance data object 1600(1) may include a database, and the data vessel associated with data element instance data object 1600(2) may include a CAD file. The flow from data element instance data object 1600(1) to 1600(2) may include a computer system reading from the database and automatically generating the CAD file and including the data element in the CAD file. In some embodiments, a dotted line between data element instance data objects 1600 may correspond with the data vessels that hold the instances of the data element not being digitally connected and that the flow of the data element from one of the data vessels to the other data vessel is not a digital flow. For example, the data element may include the dimensions of the physical component, the data vessel associated with data element instance data object 1600(4) may include an email, and the data vessel associated with data element instance data object 1600(5) may include an engineer's notepad. The flow from data element instance data object 1600(4) to 1600(5) may include an engineer reading the email and copying the dimensions from the email to the notepad.

In some embodiments, the connection between two or more data element instance data objects 1600 may include a digital connection (solid line) in response to (1) the data vessel type 1602(6) of both data element instance data objects 1600 having a “digital” value 1304, (2) the destination data element instance data object 1600 having a “digital” value 1304, or (3) the originating data element instance data object 1600 having a “digital” value 1304. The connection between two or more data element instance data objects 1600 may include a non-digital connection (dotted line) in response to (1) the data vessel type 1602(6) of both data element instance data objects 1600 having a “non-digital” value 1304, (2) the destination data element instance data object 1600 having a “non-digital” value 1304, or (3) the originating data element instance data object 1600 having a “non-digital” value 1304. The step of storing the ordered subset of data element instance data objects 1600 (step 1510) may include storing the data element instance data objects 1600 in a second data storage. The second data storage may be different from the first data storage of step 1502 or may be same data storage. Step 1510 may include storing metadata associated with the data element instance data objects 1600.

The method 1500 may further include displaying a visual representation of the data element instance data objects 1600. This visual representation may include viewing the connections between the data element instance data objects 1600. Displaying the visual representation may include displaying the visual representation on a graphical UI (GUI). The GUI may be displayed on a computing device's monitor, screen, touchscreen, or other visual output device. Displaying the visual representation may include displaying graphical elements in a similar manner to the system 1700 of FIG. 17. Displaying the visual representation may include displaying a visual indication of whether a data element instance is stored in a digital or non-digital data vessel. This visual indication may be based on the data vessel type 1602(6) of the data element instance data object 1600. The visual indication may include a dotted arrow, as is shown in FIG. 17, or may include another visual indication. In some embodiments, the GUI may include graphical elements that a user of the computing device may interact with. For example, the user may use a mouse to click on a visual representation of the data element instance data object 1600(2), or the user may touch the portion of a touchscreen that includes the visual representation of the data element instance data object 1600(2). The user interaction may include the user dragging a data element instance data object 1600 to a different location on the screen. The user interaction may include the user clicking on a data element instance data object 1600. In response to the user clicking on the data element instance data object 1600, the GUI may display information about the data element instance data object 1600. The information may include one or more of the features 1302 or values 1304 discussed above in relation to the data element instance data object 1600 of FIG. 16. In some embodiments, the visual representation of the data element instance data objects 1600 may capture the current state of data and information flows to the level of detail such that the user can determine what must happen for the right people to access the right information, at the right time, and in the right form.

In some embodiments, the visual representation of the system 1700 may display the names or identifiers of one or more actors that contributed to the data element instance corresponding to a data element instance data object 1600. The one or more actors may be derived from the one or more actors 1306(4) of a function data object 1102. For example, the one or more actors 1306(4) of the function data object 1102 that directly preceded the data vessel data object 1104 where the relevant data element instance data object 1600 is stored. In some embodiments, the method 1500 may include displaying a visual representation of the system of FIG. 12, which may show a visual representation of at least some of the function data objects 1102, data vessel data objects 1104, or the connections between these data objects. In some embodiments, the visual representation may include one or more of the actors 1306(4) displayed above their function data object 1102, which may show that the one or more actors listed contributed to the corresponding function. In some embodiments, if the location 1402(5) of a data vessel corresponding to a data vessel data object 1104 is unofficial or unknown, the visual representation of the system may include a symbol near the data vessel data object 1104.

As referenced above, the systems and method disclosed herein may improve a physical component or may improve the process of designing, fabricating, and testing the physical component. In some embodiments, improving the process of designing, fabricating, and testing may include digitally connecting the data element instances corresponding to the data element instance data objects 1600 of the system 1700. For example, as shown in FIG. 17, the connections between data element instance data objects 1600(2) and 1600(4), 1600(3) and 1600(4), 1600(4) and 1600(5), and 1600(4) and 1600(6) are non-digital connections, which signify that the data element is being manually transmitted between data vessels and functions. Digital connectivity would improve the process by unsiloing the data element from a siloed data vessel, making the data element more trackable, improving the speed at which the data element is transferred between functions, and removing human error. For example, instead of the dimensions of the physical component being written on an engineer's notepad, the dimensions can be stored in a database. In response to this new storage means, the dimensions are now unsiloed (i.e., no longer limited to the engineer's mind and the notepad), trackable (i.e., the database management system can record when the dimensions were inserted into the database and by whom, and can make a back-up of the database with the dimensions), arrive quicker at the next function (e.g., the next function can instantly read from the database instead of having to wait for the engineer to take the notepad to the next function), and less subject to human error (e.g., if the engineer were to misplace the notepad).

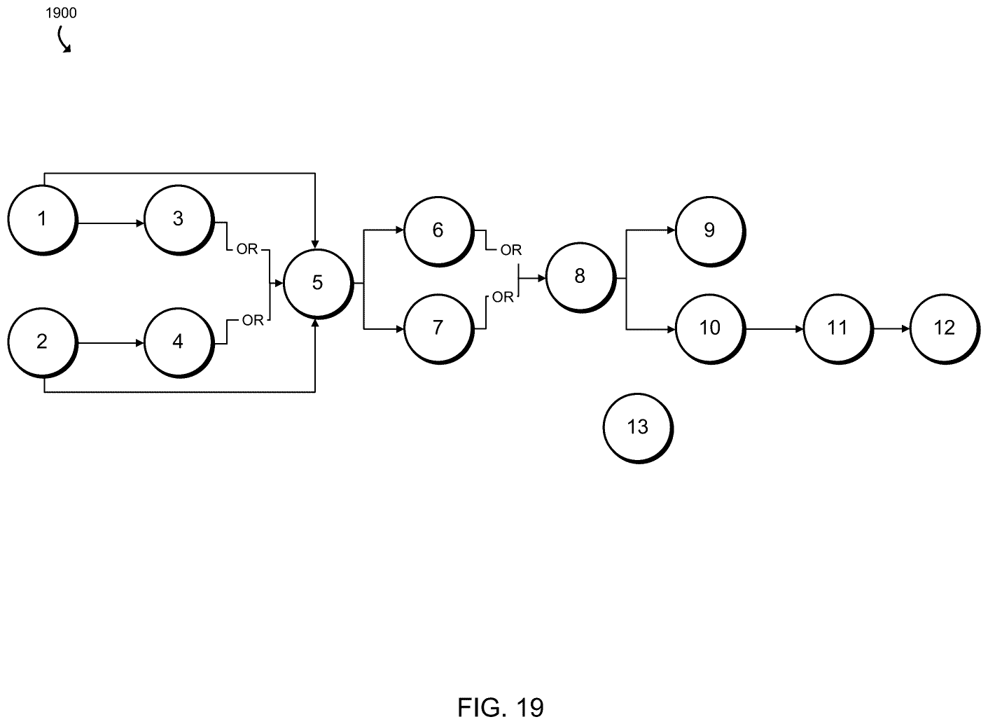

Referring back to FIG. 4, in the illustrative embodiment, the method 400 continues in block 410, which includes evaluating results of the application of the data element mapping analysis (e.g., from block 402) to identify and prioritize data threads for improvement (e.g., efficiency enhancement). The block 410 corresponds with the operation 112 of FIG. 1 and a detailed diagram 1800 of the operation 112 is shown in FIG. 18. The method 400, in the illustrative embodiment, includes obtaining data indicative of data threads within the system 200 in the current state of the system 200 (e.g., unimproved state), as indicated in block 412. In doing so, the method 400, in the illustrative embodiment, includes obtaining data indicative of one or more functions, one or more data vessels, and one or more data element level views (e.g., generated from the analysis in block 402), as indicated in block 414. Further, and as indicated in block 416, the method 400 illustratively includes creating a directed graph data structure in which nodes represent data element instances and edges (e.g., arcs) between the nodes indicate linked relationships. An embodiment of a directed graph data structure 1900 that may be produced according to block 416 is shown in FIG. 19. In creating the directed graph data structure, the method 400, in the illustrative embodiment, includes creating the directed graph data structure based on a table data structure (e.g., a spreadsheet file, a database table, etc.) representative of the obtained data (e.g., from block 412), as indicated in block 418. In doing so, and as indicated in block 420, the method 400 may include creating the directed graph data structure based on a table data structure in which rows represent data element instances, as indicated in block 420. Further, and as indicated in block 422, the method 400 may include creating the directed graph data structure based on a table data structure in which the columns represent attributes of each corresponding data element instance.

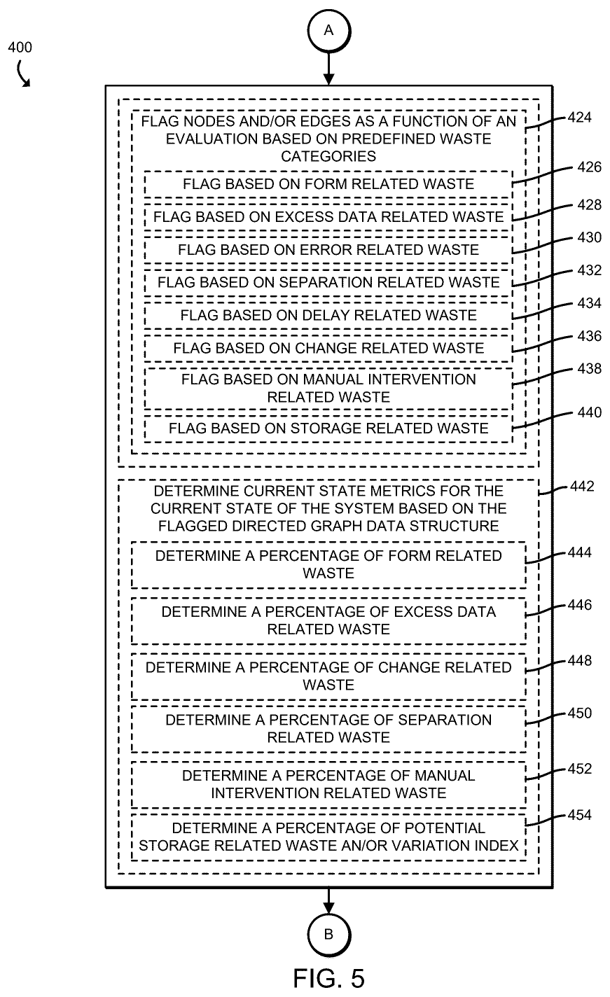

Referring now to FIG. 5, the method 400, in the illustrative embodiment, includes flagging nodes and/or edges of the directed graph data structure as a function of (e.g., based on) an evaluation based on predefined waste categories, as indicated in block 424. In doing so, the method 400 may include flagging based on form related waste, as indicated in block 426. Form related waste may be embodied as waste resulting from data or information being arranged or encoded in a format that is determined to be sub-optimal for use. The form related waste may be determined directly from node data (e.g., from the nodes of the directed graph data structure). In at least some embodiments, if a column of the table data structure indicative of the data format indicates that the corresponding data element instance has an unstructured data format, the data element instance may be identified as representing form related waste. Additionally, the method 400 may include flagging nodes and/or edges of the directed graph data structure based on excess data related waste, as indicated in block 428. Excess data related waste may result from a determination that a greater amount or volume of data or information than needed is present. In at least some embodiments, excess data related waste may be determined by flagging edges (e.g., arcs) where actors and a data element name of a parent node are the same as a corresponding child node. Additionally or alternatively, excess data related waste may be determined from edge (e.g., arc) data if the edge (e.g., arc) is conditional (e.g., utilizes an OR statement).

In at least some embodiments, the method 400 may include flagging one or more nodes and/or edges of the directed graph data structure based on error related waste, as indicated in block 430. Error related waste may be embodied as data that has been determined to be incorrect, inaccurate, or incomplete. In at least some embodiments, the method 400 may include determining error related waste directly from node data. The method 400 may include indirectly evaluating the opportunity for error based on the edge data. Error related waste may arise, for example, due to manual transfers of data in the system 200. As indicated in block 432, the method 400 may include flagging one or more nodes and/or edges based on separation related waste. Separation related waste may be embodied as data or information that lacks connectivity in a data thread. In some embodiments, separation related waste may be determined directly from edge (e.g., arc) data. For example, if the place of data storage is different for parent and child nodes, then the edge between the child node and the parent node is separated and indicative of separation related waste.

Further, in some embodiments, the method 400 may include flagging one or more nodes and/or edges based on delay related waste, as indicated in block 434. Delay related waste may be embodied as a stoppage in the flow of data or information. In at least some embodiments, the method 400 includes determining delay related waste from edge data and may include performing one or more time studies or real-time monitoring of the capture of data vessels and data element handling within the system 200. The method 400, in some embodiments, may include flagging one or more nodes or edges based on change related waste, as indicated in block 436. Change related waste may be embodied as the manipulation, modification, or transformation of data or information. In at least some embodiments, the method 400 may include determining change related waste from the edge data. That is, in at least some embodiments, if a data element instance changes from one form to another form, or from one data element to another data element, the method 400 may include determining that change related waste is present.

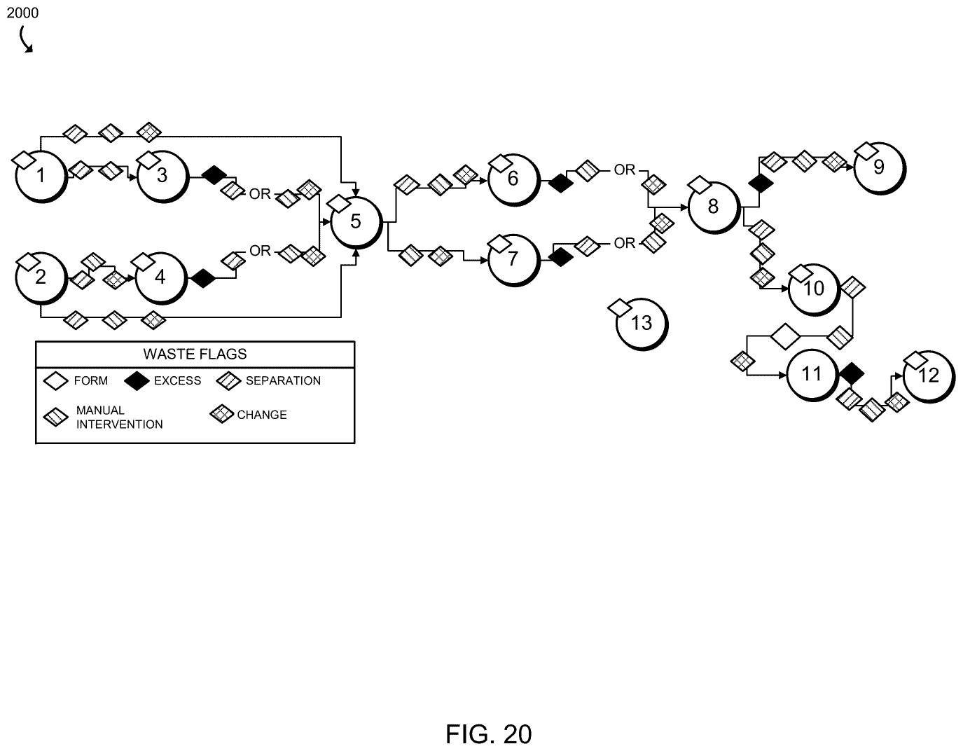

In some embodiments, the method 400 may include flagging one or more nodes and/or edges based on manual intervention related waste, as indicated in block 438. Manual intervention related waste may be embodied as manual intervention determined to be necessary to initiate or continue a flow of data or information within the system 200 (e.g., within a data thread of the system 200). In at least some embodiments, the method 400 may include determining manual intervention related waste direct from the edge data. That is, if a column of the underlying table data structure indicates that a manual transfer property associated with the data element instance is true or “yes”, then the method 400 may include determining that the edge between the child node and the parent node requires manual intervention, and as such, that manual intervention related waste is present. The method 400 may also include flagging one or more nodes and/or edges based on storage related waste, as indicated in block 440. Storage related waste may be embodied as the retaining of data that has been determined to have no apparent purpose or requirement for preservation. In some embodiments, the method 400 may include flagging one or more nodes and/or edges based on variation (also referred to EXCESS 2), which is indicative of lack of standardization in flow of data elements or in the system as a whole. The method 400 may include determining whether a data element has been used less that a predefined number of times in the directed graph data structure and, if so, flagging the corresponding node as potentially representing storage related waste. The method 400 may further include verifying that any nodes flagged as potentially representing storage related waste actually do not have a purpose or requirement for preservation. An embodiment of a flagged directed graph data structure 2000 to indicated wastes is shown in FIG. 20.

Continuing the method 400, as indicated in block 442, the method 400 may include determining current state metrics for the current state of the system 200 based on the flagged directed graph data structure (e.g., from block 424). As indicated in block 444, the method 400 may include determining a percentage of form related waste (e.g., from block 426). The percentage of form related waste may be determined as the total number of flagged form related wastes divided by the total number of data element instances (e.g., nodes) for the system (e.g., the system 200). The method 400 may also include determining a percentage of excess data related waste (e.g., from block 428). In the illustrative embodiment, the percentage of excess data related waste may be determined as the total number of flagged excess related wastes divided by the total number of data element instance relationships (e.g., edges). For individual data elements, the percentage of excess related waste may be determined by the total flagged excess related wastes for a specific data element divided by the total number of data element instance relationships (e.g., edges) for that data element. Further, and as indicated in block 448, the method 400 may include determining a percentage of change related waste (e.g., from block 436). The percentage of change related waste may be determined as the total number of flagged change related wastes divided by the total number of data element instance relationships (e.g., edges) for the system 200.

Additionally, the method 400 may include determining a percentage of separation related waste, as indicated in block 450. The separation related waste may be determined as the total number of flagged separation related wastes divided by the total number of data element instance relationships (e.g., edges) for the system 200. The method 400 may also include determining a percentage of manual intervention related waste (e.g., from block 438), as indicated in block 452. The percentage of manual intervention related waste may be determined as the total number of manual intervention related wastes divided by the total number of data element instance relationships (e.g., edges) for the system (e.g., the system 200). Additionally or alternatively, the method 400 may include determining a percentage of potential storage related waste (e.g., from block 440), as indicated in block 454. The percentage of potential storage related waste may be determined as the total number of flagged potential storage related wastes divided by the total number of data element instances (e.g., nodes) for the system (e.g., the system 200). As also indicated in block 454, the method 400 may include determining a variation index, indicative of a lack of standardization (e.g., variation) in a flow of data elements or the system as a whole. For the system, the variation index is calculated as the total number of flagged EXCESS 2 wastes divided by the total number of data element instance relationships (e.g., arcs). For individual data elements, the variation index is calculated as the total flagged EXCESS 2 wastes for a specific data element divided by the total number of data element instance relationships (e.g., arcs) for that data element.

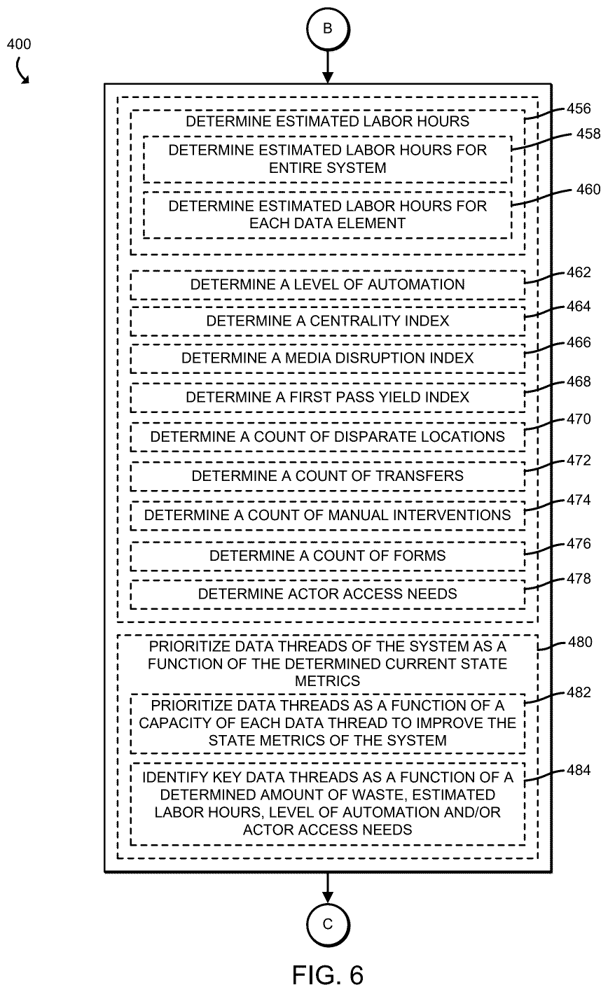

Referring now to FIG. 6, in the determination of current state metrics, the method 400 may include determining estimated labor hours, as indicated in block 456. In doing so, the method 400 may include determining estimated labor hours for the entire system (e.g., the system 200), as indicated in block 458. The estimated labor hours for the entire system may be determined by adding labor hour metrics for all nodes. Additionally or alternatively, the method 400 may include determining estimated labor hours for each data element, as indicated in block 460. The estimate labor hours for each data element may be determined by adding the labor hour metrics for each node of a data element instance. Continuing the method 400, as indicated in block 462, the method 400 may include determining a level of automation. The level of automation may be determined as the total number of non-manual data element transfers divided by the total number of data element instance relationships (e.g., edges). The method 400 may also include determining the level of automation for data elements (e.g., total non-manual data element transfers for one data element divided by the total number of transfers for that one data element). Additionally, the method 400 may include determining a centrality index, as indicated in block 464. The centrality index may be determined per place of storage and may be embodied as the quotient between the number of transfers to the place of storage and the number of total data element instance relationships (e.g., edges). Places of storage may include official places of storage such as shared drives and organizational portals and unofficial places of storage, such as an actor's memory and/or email directories.

Still referring to FIG. 6, in determining the current state metrics, the method 400 may include determining a media disruption index, as indicated in block 466. The media disruption index may be determined as the total number of transfers from digital form to paper form and from conversation (e.g., auditory) form to paper form divided by the total number of data element instances relationships (e.g., edges) for the system (e.g., the system 200). The method 400 may include determining a first pass yield index, as indicated in block 468. The first pass yield index may be embodied as one minus the quotient of the number of data element instances (e.g., for one data element) divided by the total number of data element instances relationships (e.g., edges). In the illustrative embodiment, the method 400 includes calculating the first pass yield index for each unique data element. The method 400 may also include determining a count of disparate locations, as indicated in block 470. The count of disparate locations may be determined as the count of unique places of storage used in the system (e.g., the system 200) and the number of times each storage place is used in data element instances (e.g., nodes).

Further, the method 400 may include determining a count of transfers, as indicated in block 472. In determining the count of transfers, the method 400 may include a count of data element instances (e.g., nodes) for a unique data element. The method 400 may also include determining a count of manual interventions, as indicated in block 474. In determining the count of manual interventions, the method 400 may include determining a count of data element instances (e.g., nodes) with manual transfer for each unique data element. Additionally, the method 400 may include determining a count of forms, as indicated in block 476. The determination of the count of forms may include determining a count of unique forms used in the system (e.g., the system 200) and the number of times each form is used in data element instances (e.g., nodes). Further, in determining the current state metrics, the method 400 may include determining actor access needs, as indicated in block 478. The actor access needs may be determined as the number of times that a data element or data vessel changes actor access.

After calculation of the current state metrics, the method 400 may include prioritizing data threads of the system (e.g., the system 200) as a function of the determined current state metrics, as indicated in block 480. In doing so, the method 400 may include prioritizing data threads as a function of a capacity of each data thread to improve the state metrics of the system (e.g., the system 200), as indicated in block 482. Further, and as indicated in block 484, the method 400 may include identifying key (e.g., critical, highly prioritized, etc.) data threads as a function of a determined amount of waste (e.g., prioritizing a data thread higher if it has more waste than less waste), estimated labor hours (e.g., greater labor hours resulting in a higher prioritization of the data thread), level of automation, and/or actor access needs.

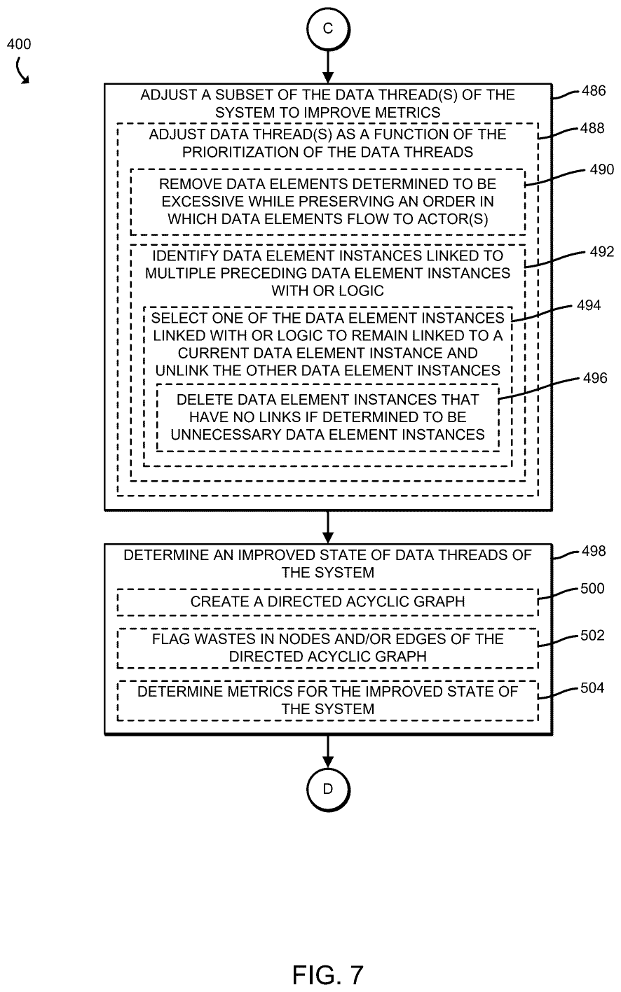

Referring now to FIG. 7, the method 400, in the illustrative embodiment, continues in block 486, which includes adjusting a subset of the data threads of the system (e.g., the system 200) to improve the metrics (e.g., provide an improvement over the current state metrics determined in block 442). That is, rather than attempting to adjust all of the data threads of the system on the initial iteration of the method 400, which could result in insurmountable resource requirements (e.g., time, money, etc.), the method 400 includes selecting a subset of the data threads for adjustment based on the impact (e.g., amount of improvement to the metrics) that the adjustments will provide.

As indicated in block 488, the method 400 includes adjusting one or more data threads of the system (e.g., the system 200) as a function of the prioritization of the data threads (e.g., from block 480). In doing so, and as indicated in block 490, the method 400 may include removing data elements that have been determined to be excessive while preserving an order in which data elements flow to actors in the system (e.g., the system 200). Additionally, and as indicated in block 492, the method 400 may include identifying data element instances that are linked to multiple preceding data element instances using OR logic. Further, in the illustrative embodiment, the method 400 includes selecting one of the data element instances linked with OR logic to remain linked to a current data element instance and unlinking the other data element instances, as indicated in block 494. After performance of the unlinking operation, the method 400, in the illustrative embodiment, includes deleting (e.g., from the directed graph data structure) data element instances that have no links if they are determined to be unnecessary data element instances, as indicated in block 496.

Afterwards, the method 400, in the illustrative embodiment, advances to block 498, which corresponds to the operation 114 of FIG. 1. A detailed diagram 2100 of the operation 114 is shown in FIG. 21. The block 498 includes determining an improved state of data threads of the system 200. In doing so, the method 400 may include creating a directed acyclic graph data structure, similar to the block 416 described above, as indicated in block 500. Further, the method 400, in the illustrative embodiment, includes flagging wastes in nodes and/or edges of the directed acyclic graph data structure, as indicated in block 502. In flagging the wastes, the method 400 may include the operations associated with block 424, described above. Additionally, the method 400, in the illustrative embodiment, includes determining metrics for the improved state of the system (e.g., for the adjusted data threads), as indicated in block 504. The method 400 may include determining those metrics for the improved state of data threads of the system through the operations described with reference to block 442.

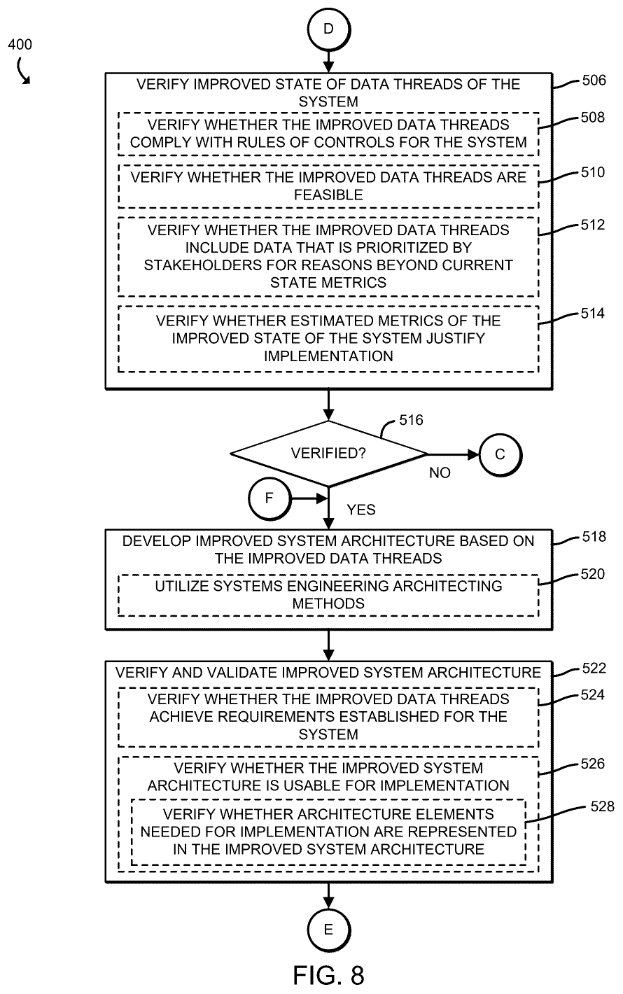

In the illustrative embodiment, the method 400 advances to block 506 of FIG. 8, which includes verifying the improved state of data threads of the system (e.g., the system 200) Block 506 corresponds to the operation 116 of FIG. 1, which is shown in more detail in the diagram 2200 of FIG. 22. In verifying the improved state, the method 400 may include verifying whether the improved data threads (e.g., the adjusted data threads in the subset from block 486) comply with rules of controls for the system, as indicated in block 508. The method 400 may also include verifying whether the improved data threads are technically feasible, as indicated in block 510. Further, the method 400 may include verifying whether the improved data threads include data that is prioritized by stakeholders for reasons beyond the current state metrics, as indicated in block 512. In addition, the method 400 may include verifying whether estimated metrics of the improved state of the system justify implementation of the adjustments to the data threads, as indicated in block 514.

In block 516, in response to a determination that the improved state of data threads of the system were not verified, the method 400 loops back to block 486 of FIG. 7 to readjust a subset of the data threads. Otherwise, if the improved state is verified, the method 400 advances to block 518, which includes developing an improved system architecture based on the improved (e.g., adjusted) data threads. Block 518 corresponds with the operation 118 of FIG. 1. A detailed diagram 2300 of the operation 118 is shown in FIG. 23. In developing an improved system architecture, the method 400 may include utilizing one or more systems engineering architecting methods to develop the improved system architecture based on the improved (e.g., adjusted) data threads, as indicated in block 520. Afterwards, the method 400 advances to block 522, which includes verifying and validating the improved system architecture (e.g., from block 518). Block 522 corresponds with the operation 120 of FIG. 1. A detailed diagram 2400 of the operation 120 is shown in FIG. 24. As indicated in block 524, the method 400 may include verifying whether the improved (e.g., adjusted) data threads achieve requirements established for the system (e.g., the system 200). Additionally, in verifying and validating the improved system architecture, the method 400 may include verifying whether the improved system architecture (e.g., data representing the design of the improved system architecture) is usable for implementation, as indicated in block 526. In doing so, the method 400 may include verifying whether architecture elements needed for implementation are represented in the improved system architecture, as indicated in block 528.

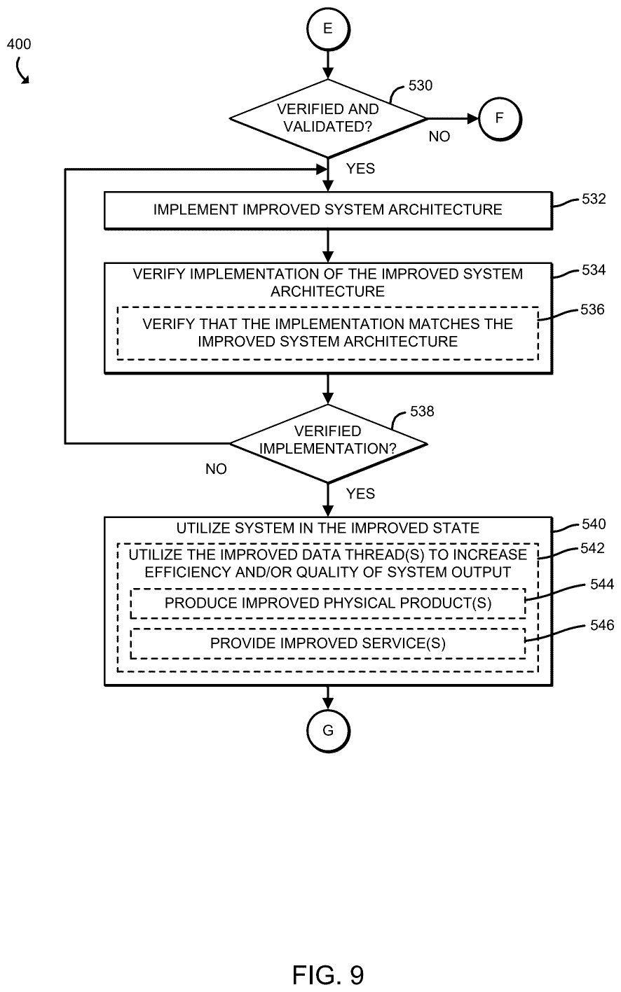

In the illustrative embodiment, the method 400 advances to block 530 of FIG. 9 which includes determining the subsequent course of action based on whether the improved system architecture was verified and validated in block 522. If not, the method 400 loops back to block 518 of FIG. 8 to redevelop the improved system architecture. Otherwise, the method 400 advances to block 532, which includes implementing the improved system architecture. Block 532 corresponds with the operation 122 of FIG. 1. A detailed diagram 2500 of the operation 122 is shown in FIG. 25. Subsequently, the method 400, in the illustrative embodiment, includes verifying the implementation of the improved system architecture, as indicated in block 534. The operation 124 of FIG. 1 corresponds with block 534.

A detailed diagram 2600 of the operation 124 is shown in FIG. 26. In verifying the implementation, the method 400 may include verifying that the implementation matches the improved system architecture (e.g., the design for the improved system architecture from block 518), as indicated in block 536. Subsequently, the method 400 advances to block 538, which includes determining the subsequent course of action based on whether the implementation of the improved system architecture was verified (e.g., in block 534). If not, the method 400 loops back to block 532 to re-implement the improved system architecture. Otherwise, if the improved system architecture was verified, the method 400 advances to block 540, which includes utilizing the system (e.g., the system 200) in its improved state (e.g., with the adjusted data thread(s)). In utilizing the improved system, the method 400 illustratively includes utilizing the improved (e.g., adjusted) data threads to increase efficiency and/or quality (e.g., through reduced waste) of system output (e.g., the output 250), as indicated in block 542.

In doing so, the method 400 may include producing improved physical products (e.g., the products 252), as indicated in block 544 and/or providing improved services (the services 254), as indicated in block 546. As described above, and as indicated in FIG. 1, the method 400 may loop back to the beginning (e.g., the operation 110 of FIG. 1 and block 402 of FIG. 4) to reapply the DEMA analysis to the system 200 in its improved (now current) state and potentially adjust (e.g., improve) one or more additional data threads to further reduce waste and improve the output of the system 200 as the resources of the organization 210 allow.

While certain illustrative embodiments have been described in detail in the drawings and the foregoing description, such an illustration and description is to be considered as exemplary and not restrictive in character, it being understood that only illustrative embodiments have been shown and described and that all changes and modifications that come within the spirit of the disclosure are desired to be protected. There exist a plurality of advantages of the present disclosure arising from the various features of the apparatus, systems, and methods described herein. It will be noted that alternative embodiments of the apparatus, systems, and methods of the present disclosure may not include all of the features described, yet still benefit from at least some of the advantages of such features. Those of ordinary skill in the art may readily devise their own implementations of the apparatus, systems, and methods that incorporate one or more of the features of the present disclosure.

1. A method for improving production of a physical product comprising:
applying a data element mapping analysis to a current state of a system;
evaluating results of the application of the data element mapping analysis to identify and prioritize data threads of the system for increased efficiency;
adjusting, as a function of the prioritization of the data threads, a subset of the data threads of the system to improve one or more metrics of the system associated with waste that impedes efficiency; and
utilizing the adjusted data threads to increase an efficiency associated with production of a physical product produced by the system.

2. The method of claim 1, wherein applying the data element mapping analysis comprises performing functional level mapping and analysis, data vessel mapping and analysis, and data element level mapping and analysis.

3. The method of claim 1, wherein evaluating results of the application of the data element mapping analysis comprises creating a directed graph data structure in which nodes represent data element instances and edges between the nodes indicate linked relationships.

4. The method of claim 3, wherein creating a directed graph data structure comprises creating the directed graph data structure based on a table data structure representative of obtained data indicative of functions, data vessels, and data elements associated with the data threads within the system in the current state.

5. The method of claim 4, wherein creating the directed graph data structure based on a table data structure comprises creating the directed graph data structure based on a table data structure in which rows represent data element instances and columns represent attributes of each corresponding data element instance.

6. The method of claim 3, wherein creating the directed graph data structure comprises flagging one or more of the nodes or edges as a function of an evaluation based on a set of predefined waste categories.

7. The method of claim 6, wherein flagging one or more of the nodes or edges as a function of an evaluation based on a set of predefined waste categories comprises flagging one or more of the nodes or edges based on a determined presence of form related waste, excess data related waste, error related waste, separation related waste, delay related waste, change related waste, manual intervention related waste, or storage related waste.

8. The method of claim 6, wherein evaluating results of the application of the data element mapping analysis to identify and prioritize data threads of the system further comprises determining current state metrics for the current state of the system based on the flagged directed graph structure.

9. The method of claim 8, wherein determining the current state metrics comprises determining one or more of a percentage of form related waste, a percentage of excess data related waste, a percentage of change related waste, a percentage of separation related waste, a percentage of manual intervention related waste, a percentage of potential storage related waste, a variation index, an estimated number of labor hours for the system, an estimated number of labor hours for each data element, a level of automation, a centrality index, a media disruption index, a first pass yield index, a count of disparate storage locations for data element instances, a count of transfers for data element instances, a count of manual interventions indicative of manual transfers of unique data elements, a count of forms used with each data element instance, or actor data access needs indicative of a number of times that a data element or data vessel changes actor access.

10. The method of claim 8, further comprising prioritizing the data threads of the system as a function of the determined current state metrics.

11. The method of claim 10, wherein prioritizing data threads as a function of the determined current state metrics comprises prioritizing data threads as a function of a capacity of each data thread to improve upon the current state metrics of the system.

12. The method of claim 10, wherein prioritizing data threads as a function of the determined current state metrics comprises identifying one or more key data threads as a function of one or more of a determined amount of waste, estimated labor hours, level of automation, or actor access needs.

13. The method of claim 1, wherein adjusting a subset of the data threads as a function of the prioritization of the data threads comprises removing one or more data elements determined to be excessive while preserving an order in which the data elements flow to one or more actors.

14. The method of claim 1, wherein adjusting a subset of the data threads as a function of the prioritization of the data threads comprises identifying one or more data element instances linked to multiple preceding data element instances with OR logic.

15. The method of claim 14, further comprising selecting one of the data element instances linked with OR logic to remain linked to a current data element instance and unlinking other data element instances.

16. The method of claim 15, further comprising deleting data element instances that have no links.

17. The method of claim 1, further comprising:
determining an improved state of the data threads of the system;
verifying the improved state of the data threads of the system;
developing an improved system architecture based on the improved state of the data threads;
verifying and validating the improved system architecture;
implementing the improved system architecture; and
verifying implementation of the improved system architecture.

18. The method of claim 1, further comprising, after utilizing the adjusted data threads to increase an efficiency associated with production, adjusting, as a function of the prioritization of the data threads, a second subset of the data threads to further improve the one or more metrics of the system.

19. A device comprising:
circuitry configured to:
apply a data element mapping analysis to a current state of a system;
evaluate results of the application of the data element mapping analysis to identify and prioritize data threads of the system for increased efficiency;
adjust, as a function of the prioritization of the data threads, a subset of the data threads of the system to improve one or more metrics of the system associated with waste that impedes efficiency; and
utilize the adjusted data threads to increase an efficiency associated with production of a physical product produced by the system.

20. One or more machine-readable storage media comprising a plurality of instructions stored thereon that, in response to being executed, cause a compute device to:
apply a data element mapping analysis to a current state of a system;
evaluate results of the application of the data element mapping analysis to identify and prioritize data threads of the system for increased efficiency;
adjust, as a function of the prioritization of the data threads, a subset of the data threads of the system to improve one or more metrics of the system associated with waste that impedes efficiency; and
utilize the adjusted data threads to increase an efficiency associated with production of a physical product produced by the system.
